(19) United States
(12) Patent Application Publication
(10) Pub. No.: US 2025/0089468 A1
(43) Pub. Date: Mar. 13, 2025

(54) DISPLAY DEVICE AND METHOD OF MANUFACTURING THE SAME

(71) Applicant: Samsung Display Co., LTD., Yongin-si (KR)

(72) Inventors: Seon Young CHOI, Yongin-si (KR); Gyung Soon PARK, Yongin-si (KR)

(21) Appl. No.: 18/828,914

(22) Filed: Sep. 9, 2024

(30) Foreign Application Priority Data
Sep. 11, 2023 (KR) 10-2023-0120092

(51) Int. Cl. H10K 59/122; H10K 59/12

(52) U.S. Cl. CPC H10K 59/122; H10K 59/1201

(57) ABSTRACT

A display device and a method of manufacturing the same are disclosed. A display device includes a first pixel electrode located in a first emission area of a substrate, an insulating layer covering an edge of the first pixel electrode, a first light emitting layer on the first pixel electrode and the insulating layer, a first common electrode on the first light emitting layer, a conductive layer arranged on the insulating layer to surround the first emission area, a first bank on the conductive layer, a second bank adjacent to the first emission area on the first bank and including a tip protruding from sides of the first bank, a groove recessed from an upper surface of the second bank to at least a portion of the first bank, a first organic pattern, and a first inorganic layer.

### CROSS-REFERENCE TO RELATED APPLICATION

The present application claims priority to and the benefit of Korean Patent Application No. 10-2023-0120092, filed on Sep. 11, 2023 in the Korean Intellectual Property Office, the entire disclosure of which is incorporated herein by reference.

### BACKGROUND

### 1. Field

Aspects of embodiments of the present disclosure relate to a display device and a method of manufacturing the same.

### 2. Description of the Related Art

As the information society develops, demands for display devices for displaying images are increasing in various forms. For example, display devices are applied to various electronic devices, such as smartphones, digital cameras, notebook computers, navigation devices, and smart televisions. The display devices may be flat panel display devices, such as liquid crystal display devices, field emission display devices, and organic light emitting display devices. Among these flat panel display devices, a light emitting display device includes a light emitting element that enables each pixel of a display panel to emit light by itself. Thus, the light emitting display device can display an image without a backlight unit that provides light to the display panel.

### SUMMARY

According to aspects of embodiments of the present disclosure, a display device capable of blocking moisture penetration via an organic pattern, an electrode pattern, and a capping pattern on a bank and a method of manufacturing the display device are provided.

However, aspects of the present disclosure are not restricted to those set forth herein. The above and other aspects of the present disclosure will become more apparent to one of ordinary skill in the art to which the present disclosure pertains by referencing the detailed description of the present disclosure provided below.

According to one or more embodiments of the present disclosure, a display device includes a first pixel electrode located in a first emission area of a substrate, an insulating layer covering an edge of the first pixel electrode, a first light emitting layer on the first pixel electrode and the insulating layer, a first common electrode on the first light emitting layer, a conductive layer arranged on the insulating layer to surround the first emission area, a first bank on the conductive layer, a second bank adjacent to the first emission area on the first bank and including a tip protruding from sides of the first bank, a groove recessed from an upper surface of the second bank to at least a portion of the first bank, a first organic pattern including a same material as the first light emitting layer, wherein a portion of the first organic pattern is on the second bank, and another portion of the first organic pattern is accommodated in the groove, and a first inorganic layer covering an upper surface of the first common electrode, and side surfaces of the first organic pattern arranged on the second bank and an upper surface of the first organic pattern accommodated in the groove.

The groove may be spaced apart from the first emission area with the second bank located therebetween in a plan view.

The display device may further include a first electrode pattern including a same material as the first common electrode. A portion of the first electrode pattern may be on the first organic pattern on the second bank and another portion of the first electrode pattern may be on the first organic pattern in the groove.

The display device may further include a capping layer on the first common electrode, and a first capping pattern including a same material as the capping layer. A portion of the first capping pattern may be on the first electrode pattern on the second bank and another portion of the first capping pattern may be on the first electrode pattern in the groove.

The first inorganic layer may cover side surfaces of the first electrode pattern arranged on the second bank, upper and side surfaces of the first capping pattern arranged on the second bank, and an upper surface of the first capping pattern in the groove.

A depth of the groove may be greater than a sum of a thickness of the first organic pattern, a thickness of the first electrode pattern, and a thickness of the first capping pattern.

The display device may further include a second pixel electrode located in a second emission area of the substrate, a second light emitting layer on the second pixel electrode, and a second common electrode on the second light emitting layer.

Each of the first and second common electrodes may be in contact with side surfaces of the conductive layer and upper surfaces of edges of the conductive layer.

The first and second common electrodes may be electrically connected through the conductive layer.

The display device may further include a second organic pattern including a same material as the second light emitting layer. A portion of the second organic pattern may be on the second bank and another portion of the second organic pattern may be accommodated in the groove. The display device may further include a second electrode pattern including a same material as the second common electrode. A portion of the second electrode pattern may be on the second organic pattern on the second bank and another portion of the second electrode pattern may be on the second organic pattern in the groove.

The display device may further include a second inorganic layer covering an upper surface of the second common electrode, side surfaces of the second organic pattern arranged on the second bank, side surfaces of the second electrode pattern arranged on the second bank, and an upper surface of the second organic pattern accommodated in the groove.

The groove may penetrate from the upper surface of the second bank to a lower surface of the first bank to expose an upper surface of the conductive layer.

The another portion of the first organic pattern may be accommodated in the groove to be directly disposed on the conductive layer.

According to one or more embodiments of the present disclosure, a display device includes a first pixel electrode located in a first emission area of a substrate, an insulating layer covering an edge of the first pixel electrode, a first light emitting layer on the first pixel electrode and the insulating layer, a first common electrode on the first light emitting layer, a first bank arranged on the insulating layer to surround the first emission area, a second bank arranged adjacent to the first emission area on the first bank and comprising a tip protruding from sides of the first bank, a groove recessed from an upper surface of the second bank to at least a portion of the first bank, and a first organic pattern including a same material as the first light emitting layer, wherein a portion of the first organic pattern is on the second bank, and another portion of the first organic pattern is accommodated in the groove.

The display device may further include a first electrode pattern including a same material as the first common electrode. A portion of the first electrode pattern may be arranged on the first organic pattern on the second bank, and another portion of the first electrode pattern may be arranged on the first electrode pattern accommodated in the groove. The display device may further include a first inorganic layer covering an upper surface of the first common electrode, side surfaces of the first organic pattern arranged on the second bank, side surfaces of the first electrode pattern arranged on the second bank, and an upper surface of the first electrode pattern accommodated in the groove.

According to one or more embodiments of the present disclosure, a method of manufacturing a display device includes forming first and second pixel electrodes on a substrate, sequentially stacking a sacrificial layer, an insulating layer, a conductive layer, a first bank, and a second bank on the first and second pixel electrodes, forming tips of the second bank which protrude from sides of the first bank by etching the second bank, the first bank, and the conductive layer, and forming a groove recessed from an upper surface of the second bank to at least a portion of the first bank, exposing the first and second pixel electrodes by etching the insulating layer and the sacrificial layer, and forming a first light emitting layer on the first pixel electrode, forming a portion of a first organic pattern on the second bank, and forming another portion of the first organic pattern in the groove.

The method may further include forming a first common electrode on the first light emitting layer, forming a portion of a first electrode pattern on the first organic pattern on the second bank, and forming another portion of the first electrode pattern on the first organic pattern in the groove, and forming a capping layer on the first common electrode, forming a portion of a first capping pattern on the first electrode pattern on the second bank, and forming another portion of the first capping pattern on the first electrode pattern in the groove.

The method may further include forming a first inorganic layer covering an upper surface of the capping layer, side surfaces of the first organic pattern on the second bank, side surfaces of the first electrode pattern on the second bank, upper and side surfaces of the first capping pattern on the second bank, and the upper surface of the first capping pattern in the groove.

The method may further include etching the first inorganic layer, the first capping layer, the first capping pattern, the first electrode pattern, and the first organic pattern overlapping the second pixel electrode.

The method may further include forming a second light emitting layer on the second pixel electrode, forming a portion of a second organic pattern on the second bank, and forming another portion of the second organic pattern in the groove.

In a display device and a method of manufacturing the same according to one or more embodiments, a portion of an organic pattern, a portion of an electrode pattern, and a portion of a capping pattern are formed on the bank, and another portion of the organic pattern, another portion of the electrode pattern and another portion of the capping pattern are formed in a groove in the bank, and the sides of the organic pattern, the electrode pattern, and the organic pattern on the bank are covered with an inorganic layer. Accordingly, a moisture penetration via the organic pattern, the electrode pattern, and the capping pattern is blocked, thereby improving the reliability of light emitting elements.

However, aspects and effects of the present disclosure are not limited to those described above, and other aspects and effects of the present disclosure will be apparent to those skilled in the art from the following descriptions.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view of a display device according to an embodiment;

FIG. 2 is a cross-sectional view of the display device according to an embodiment;

FIG. 3 is a plan view of a display unit of the display device according to an embodiment;

FIG. 4 is a cross-sectional view illustrating pixels of the display device according to an embodiment;

FIG. 5 is an enlarged view of a region “A1” of FIG. 4;

FIG. 6 is a cross-sectional view illustrating pixels of a display device according to an embodiment;

FIG. 7 is an enlarged view of a region “A2” of FIG. 6;

FIG. 8 is a cross-sectional view illustrating pixels of a display device according to an embodiment;

FIG. 9 is an enlarged view of a region “A3” of FIG. 8;

FIGS. 10 to 17 are cross-sectional views illustrating a process of manufacturing a display device according to an embodiment;

FIG. 18 illustrates a virtual reality device including a display device according to an embodiment;

FIGS. 19 and 20 illustrate a head mounted display including a display device according to an embodiment;

FIG. 21 is a cross-sectional view illustrating pixels according to an embodiment in the display devices of FIGS. 18 to 20;

FIG. 22 is a cross-sectional view illustrating pixels according to an embodiment in the display devices of FIGS. 18 to 20; and

FIG. 23 is a cross-sectional view illustrating pixels according to an embodiment in the display devices of FIGS. 18 to 20.

### DETAILED DESCRIPTION

In the following description, for the purposes of explanation, some details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It will be apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but are not necessarily exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or aspects, etc. (herein individually or collectively referred to as “elements”), of the various embodiments may be otherwise combined, separated, interchanged, and/or rearranged without departing from the disclosure.

The use of cross-hatching and/or shading in the accompanying drawings may be generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or one or more intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XY, YZ, XZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Further, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. Also, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to cross-sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

Some embodiments may be described and illustrated in the accompanying drawings in terms of functional blocks, units, parts, and/or modules. Those skilled in the art will appreciate that these blocks, units, parts, and/or modules may be physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It is to be further understood that terms, such as those defined in commonly used dictionaries, should be interpreted as having a meaning that is consistent with their meaning in the context of the relevant art and the disclosure, and are not to be interpreted in an ideal or excessively formal sense unless clearly so defined herein.

Herein, some embodiments of the disclosure are described in further detail with reference to the accompanying drawings.

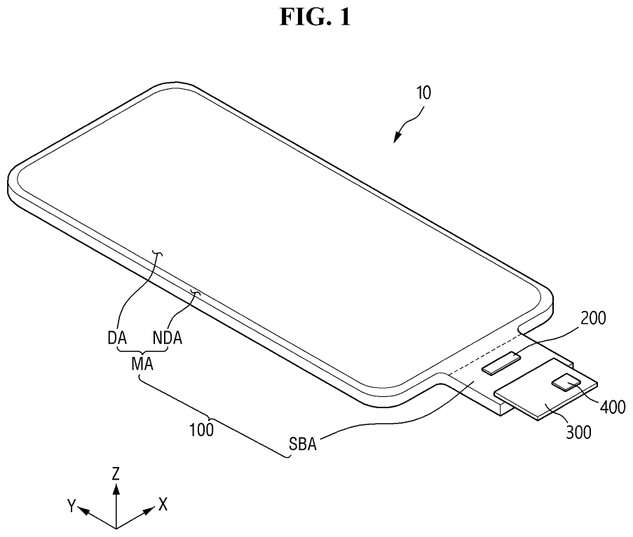

FIG. 1 is a perspective view of a display device 10 according to an embodiment.

Referring to FIG. 1, the display device 10 may be applied to portable electronic devices, such as mobile phones, smartphones, tablet personal computers (PCs), mobile communication terminals, electronic notebooks, electronic books, portable multimedia players (PMPs), navigation devices, and ultra-mobile PCs (UMPCs). For example, the display device 10 may be applied as a display unit of a television, a notebook computer, a monitor, a billboard, or an Internet of things (IoT) device. For another example, the display device 10 may be applied to wearable devices, such as smart watches, watch phones, glasses-type displays, and head mounted displays.

In an embodiment, the display device 10 may have a planar shape, such as or similar to a quadrangle. For example, the display device 10 may have a planar shape similar to a quadrangle having short sides in an X-axis direction and long sides in a Y-axis direction. In an embodiment, each corner where a short side extending in the X-axis direction meets a long side extending in the Y-axis direction may be rounded with a curvature (e.g., a predetermined curvature) or may have a right angle. However, the planar shape of the display device 10 is not limited to the quadrangular shape, but may also have a shape or be similar to other polygonal shapes, a circular shape, or an oval shape.

The display device 10 may include a display panel 100, a display driver 200, a circuit board 300, and a touch driver 400.

The display panel 100 may include a main area MA and a sub-area SBA.

The main area MA may include a display area DA including pixels that display an image and a non-display area NDA disposed around the display area DA. The display area DA may emit light from a plurality of emission areas or a plurality of opening areas. For example, the display panel 100 may include pixel circuits including switching elements, a pixel defining layer defining the emission areas or the opening areas, and self-light emitting elements.

For example, each of the self-light emitting elements may include, but is not limited to, at least one of an organic light emitting diode including an organic light emitting layer, a quantum dot light emitting diode including a quantum dot light emitting layer, an inorganic light emitting diode including an inorganic semiconductor, and a micro light emitting diode.

The non-display area NDA may be an area outside the display area DA. In an embodiment, the non-display area NDA may be defined as an edge area of the main area MA of the display panel 100. The non-display area NDA may include a gate driver (not illustrated) which supplies gate signals to gate lines and fan-out lines (not illustrated) which connect the display driver 200 and the display area DA.

The sub-area SBA may extend from a side of the main area MA. In an embodiment, the sub-area SBA may include a flexible material that can be bent, folded, rolled, etc. For example, when the sub-area SBA is bent, it may be overlapped by the main area MA in a thickness direction (Z-axis direction). The sub-area SBA may include the display driver 200 and a pad unit connected to the circuit board 300. Optionally, the sub-area SBA may be omitted, and the display driver 200 and the pad unit may be disposed in the non-display area NDA.

The display driver 200 may output signals and voltages for driving the display panel 100. The display driver 200 may supply data voltages to data lines. The display driver 200 may supply a power supply voltage to a power line and supply a gate control signal to the gate driver. The display driver 200 may be formed as an integrated circuit and mounted on the display panel 100 by a chip on glass (COG) method, a chip on plastic (COP) method, or an ultrasonic bonding method. For example, the display driver 200 may be disposed in the sub-area SBA and may be overlapped by the main area MA in the thickness direction (Z-axis direction) by bending of the sub-area SBA. As another example, the display driver 200 may be mounted on the circuit board 300.

In an embodiment, the circuit board 300 may be attached onto the pad unit of the display panel 100 using an anisotropic conductive film. Lead lines of the circuit board 300 may be electrically connected to the pad unit of the display panel 100. The circuit board 300 may be a flexible printed circuit board, a printed circuit board, or a flexible film, such as a chip on film.

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and sense a change in capacitance between the touch electrodes. For example, the touch driving signal may be a pulse signal having a certain frequency (e.g., a predetermined frequency). The touch driver 400 may determine whether an input has been made based on a change in capacitance between the touch electrodes and calculate coordinates of the input. The touch driver 400 may be formed as an integrated circuit.

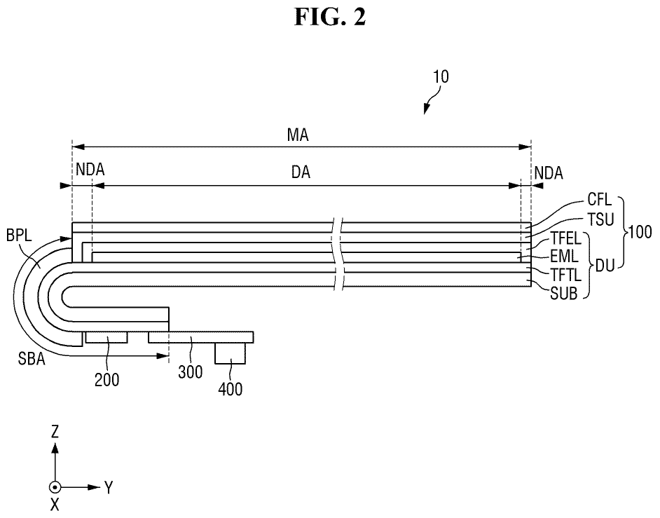

FIG. 2 is a cross-sectional view of the display device according to an embodiment.

Referring to FIG. 2, the display panel 100 may include a display unit DU, a touch sensing unit TSU, and a color filter layer CFL. The display unit DU may include a substrate SUB, a thin-film transistor layer TFTL, a light emitting element layer EML, and an encapsulation layer TFEL.

The substrate SUB may be a base substrate or a base member. The substrate SUB may be a flexible substrate that can be bent, folded, rolled, etc. For example, the substrate SUB may include a polymer resin, such as polyimide (PI), but the present disclosure is not limited thereto. For example, the substrate SUB may include a glass material or a metal material.

The thin-film transistor layer TFTL may be disposed on the substrate SUB. The thin-film transistor layer TFTL may include a plurality of thin-film transistors constituting pixel circuits of pixels. The thin-film transistor layer TFTL may further include gate lines, data lines, power lines, gate control lines, fan-out lines connecting the display driver 200 and the data lines, and lead lines connecting the display driver 200 and the pad unit. Each of the thin-film transistors may include a semiconductor region, a source electrode, a drain electrode, and a gate electrode. For example, when the gate driver is formed on a side of the non-display area NDA of the display panel 100, it may include thin-film transistors.

The thin-film transistor layer TFTL may be disposed in the display area DA, the non-display area NDA, and the sub-area SBA. The thin-film transistors of the pixels, the gate lines, the data lines, and the power lines of the thin-film transistor layer TFTL may be disposed in the display area DA. The gate control lines and the fan-out lines of the thin-film transistor layer TFTL may be disposed in the non-display area NDA. The lead lines of the thin-film transistor layer TFTL may be disposed in the sub-area SBA.

The light emitting element layer EML may be disposed on the thin-film transistor layer TFTL. The light emitting element layer EML may include a plurality of light emitting elements, each including a pixel electrode, a light emitting layer and a common electrode sequentially stacked to emit light, and a pixel defining layer defining the pixels. The light emitting elements of the light emitting element layer EML may be disposed in the display area DA.

For example, the light emitting layer may be an organic light emitting layer including an organic material. In an embodiment, the light emitting layer may include a hole transporting layer, an organic light emitting layer, and an electron transporting layer. When the pixel electrode receives a certain voltage (e.g., a predetermined voltage) through a thin-film transistor of the thin-film transistor layer TFTL and the common electrode receives a cathode voltage, holes may move to the organic light emitting layer through the hole transporting layer, and electrons may move to the organic light emitting layer through the electron transporting layer. Then, the holes and the electrons may be recombined with each other in the organic light emitting layer to emit light. For example, the pixel electrode may be an anode electrode, and the common electrode may be a cathode electrode, but the present disclosure is not limited thereto.

As another example, each of the light emitting elements may include a quantum dot light emitting diode including a quantum dot light emitting layer, an inorganic light emitting diode including an inorganic semiconductor, or a micro light emitting diode.

The encapsulation layer TFEL may cover upper and side surfaces of the light emitting element layer EML and may protect the light emitting element layer EML. The encapsulation layer TFEL may include at least one inorganic layer and at least one organic layer to encapsulate the light emitting element layer EML.

The touch sensing unit TSU may be disposed on the encapsulation layer TFEL. The touch sensing unit TSU may include a plurality of touch electrodes for sensing a user's touch in a capacitive manner and touch lines connecting the touch electrodes and the touch driver 400. For example, the touch sensing unit TSU may sense a user's touch in a mutual capacitance manner or a self-capacitance manner.

As another example, the touch sensing unit TSU may be disposed on a separate substrate disposed on the display unit DU. In this case, the substrate supporting the touch sensing unit TSU may be an encapsulation substrate that encapsulates the display unit DU.

The touch electrodes of the touch sensing unit TSU may be disposed in a touch sensor area overlapping the display area DA. The touch lines of the touch sensing unit TSU may be disposed in a touch peripheral area overlapping the non-display area NDA.

The color filter layer CFL may be disposed on the touch sensing unit TSU. The color filter layer CFL may include a plurality of color filters corresponding to a plurality of emission areas, respectively. Each of the color filters may selectively transmit light of a specific wavelength and block or absorb light of other wavelengths. The color filter layer CFL may absorb a part of light coming from the outside of the display device 10, thereby reducing reflected light caused by the external light. Therefore, the color filter layer CFL can prevent or substantially prevent color distortion caused by reflection of external light.

In an embodiment, the color filter layer CFL is directly disposed on the touch sensing unit TSU, such that the display device 10 may not require a separate substrate for the color filter layer CFL. Therefore, a thickness of the display device 10 can be relatively reduced.

The sub-area SBA of the display panel 100 may extend from a side of the main area MA. The sub-area SBA may include a flexible material that can be bent, folded, rolled, etc. For example, when the sub-area SBA is bent, it may be overlapped by the main area MA in the thickness direction (Z-axis direction). The sub-area SBA may include the display driver 200 and the pad unit electrically connected to the circuit board 300.

The display device 10 may include a bending protection layer BPL which protects the sub-area SBA. The bending protection layer BPL may be disposed on a thin film transistor layer TFTL of the bent sub-area SBA. The bending protection layer BPL may protect the thin film transistor layer TFTL of the bent sub-area SBA and minimize or reduce tensile stress of the sub-area SBA.

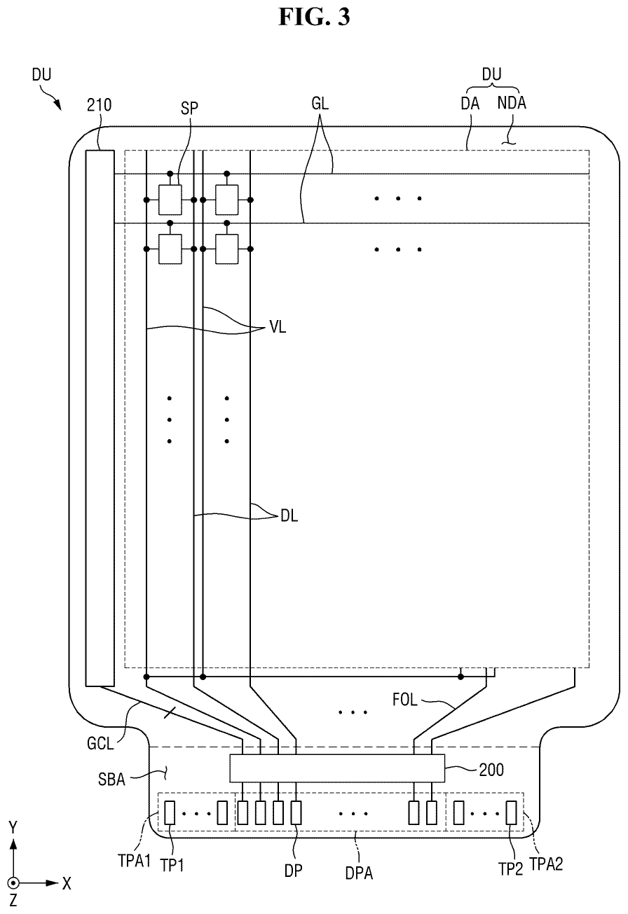

FIG. 3 is a plan view of a display unit of the display device according to an embodiment.

Referring to FIG. 3, the display unit DU may include the display area DA and the non-display area NDA.

The display area DA is an area for displaying an image and, in an embodiment, may be defined as a central area of the display panel 100. The display area DA may include a plurality of pixels SP, a plurality of gate lines GL, a plurality of data lines DL, and a plurality of power lines VL. Each of the pixels SP may be defined as a minimum unit that outputs light.

The gate lines GL may supply gate signals received from a gate driver 210 to the pixels SP. The gate lines GL may extend in the X-axis direction and may be spaced apart from each other in the Y-axis direction intersecting the X-axis direction.

The data lines DL may supply data voltages received from the display driver 200 to the pixels SP. The data lines DL may extend in the Y-axis direction and may be spaced apart from each other in the X-axis direction.

The power lines VL may supply a power supply voltage received from the display driver 200 to the pixels SP. Here, the power supply voltage may be at least one of a driving voltage, an initialization voltage, a reference voltage, a bias voltage, and a low potential voltage. The power lines VL may extend in the Y-axis direction and may be spaced apart from each other in the X-axis direction.

In an embodiment, the non-display area NDA may surround the display area DA. The non-display area NDA may include the gate driver 210, fan-out lines FOL, and gate control lines GCL. The gate driver 210 may generate a plurality of gate signals based on a gate control signal and sequentially supply the gate signals to the gate lines GL according to a set order.

The fan-out lines FOL may extend from the display driver 200 to the display area DA. The fan-out lines FOL may supply data voltages received from the display driver 200 to the data lines DL.

The gate control lines GCL may extend from the display driver 200 to the gate driver 210. The gate control lines GCL may supply a gate control signal received from the display driver 200 to the gate driver 210.

The sub-area SBA may include the display driver 200, a display pad area DPA, and first and second touch pad areas TPA1 and TPA2.

The display driver 200 may output signals and voltages for driving the display panel 100 to the fan-out lines FOL. The display driver 200 may supply data voltages to the data lines DL through the fan-out lines FOL. The data voltages may be supplied to the pixels SP and may determine luminances of the pixels SP. The display driver 200 may supply a gate control signal to the gate driver 210 through the gate control lines GCL.

The display pad area DPA, the first touch pad area TPA1, and the second touch pad area TPA2 may be disposed at an edge of the sub-area SBA. The display pad area DPA, the first touch pad area TPA1, and the second touch pad area TPA2 may be electrically connected to the circuit board 300 using a low-resistance high-reliability material, such as an anisotropic conductive film or self-assembly anisotropic conductive paste (SAP).

The display pad area DPA may include a plurality of display pad units DP. In an embodiment, the display pad units DP may be electrically connected to a graphics system through the circuit board 300. The display pad units DP may be connected to the circuit board 300 to receive digital video data and may supply the digital video data to the display driver 200.

The first touch pad area TPA1 may be disposed on a side of the display pad area DPA and may include a plurality of first touch pad units TP1. The first touch pad units TP1 may be electrically connected to the touch driver 400 disposed on the circuit board 300. The first touch pad units TP1 may supply touch driving signals to a plurality of driving electrodes through a plurality of driving lines.

The second touch pad area TPA2 may be disposed on the other side of the display pad area DPA and may include a plurality of second touch pad units TP2. The second touch pad units TP2 may be electrically connected to the touch driver 400 disposed on the circuit board 300. The touch driver 400 may receive touch sensing signals through a plurality of sensing lines connected to the second touch pad units TP2 and sense a change in mutual capacitance between the driving electrodes and sensing electrodes.

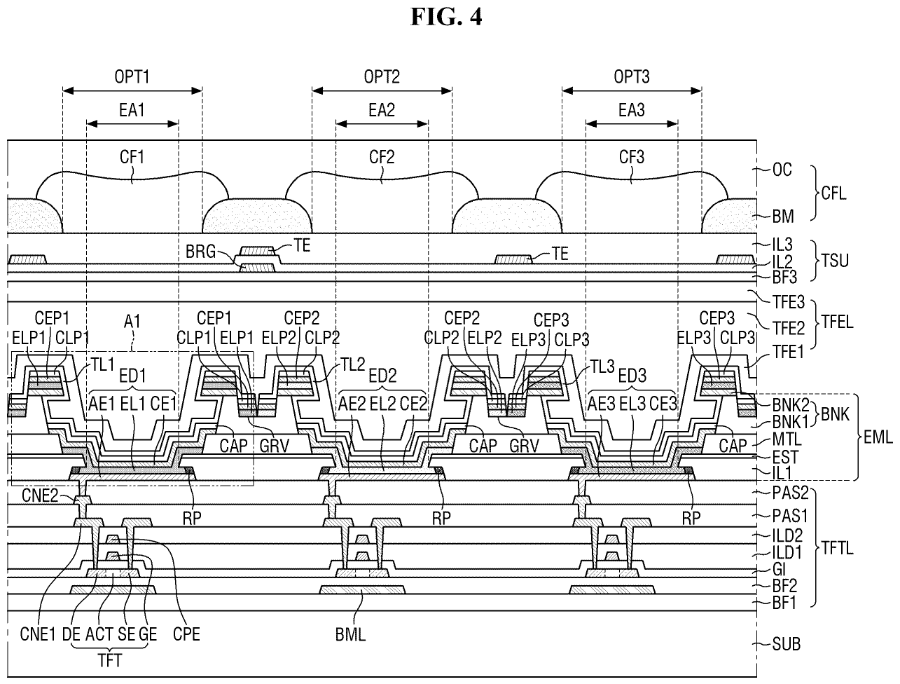

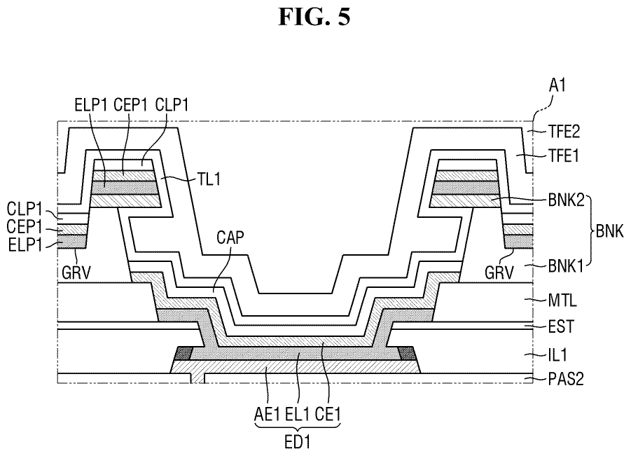

FIG. 4 is a cross-sectional view illustrating pixels of the display device according to an embodiment; and FIG. 5 is an enlarged view of a region “A1” of FIG. 4.

Referring to FIGS. 4 and 5, the display panel 100 may include the display unit DU, the touch sensing unit TSU, and the color filter layer CFL. The display unit DU may include the substrate SUB, the thin-film transistor layer TFTL, the light emitting element layer EML, and the encapsulation layer TFEL.

The substrate SUB may be a base substrate or a base member. The substrate SUB may be a flexible substrate that can be bent, folded, rolled, etc. For example, the substrate SUB may include a polymer resin, such as polyimide (PI), but the present disclosure is not limited thereto. As another example, the substrate SUB may include a glass material or a metal material.

In an embodiment, the thin-film transistor layer TFTL may include a first buffer layer BF1, light blocking layers BML, a second buffer layer BF2, thin-film transistors TFT, a gate insulating layer GI, a first interlayer insulating layer ILD1, capacitor electrodes CPE, a second interlayer insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic layer that can prevent or substantially prevent penetration of air or moisture. For example, the first buffer layer BF1 may include a plurality of inorganic layers stacked alternately.

The light blocking layers BML may be disposed on the first buffer layer BF1. For example, each of the light blocking layers BML may be a single layer or a multilayer made of any one or more of molybdenum (Mo), aluminum (Al), chromium (Cr), gold (Au), titanium (Ti), nickel (Ni), neodymium (Nd), copper (Cu), and alloys thereof. As another example, each of the light blocking layers BML may be an organic layer including a black pigment.

The second buffer layer BF2 may be disposed on the first buffer layer BF1 and the light blocking layers BML. The second buffer layer BF2 may include an inorganic layer that can prevent or substantially prevent penetration of air or moisture. For example, the second buffer layer BF2 may include a plurality of inorganic layers stacked alternately.

The thin-film transistors TFT may be disposed on the second buffer layer BF2 and may constitute pixel circuits of pixels. For example, each of the thin-film transistors TFT may be a driving transistor or a switching transistor of a pixel circuit. Each of the thin-film transistors TFT may include a semiconductor region ACT, a source electrode SE, a drain electrode DE, and a gate electrode GE.

The semiconductor region ACT, the source electrode SE, and the drain electrode DE may be disposed on the second buffer layer BF2. The semiconductor region ACT, the source electrode SE, and the drain electrode DE may overlap a light blocking layer BML in the thickness direction. The semiconductor region ACT may be overlapped by the gate electrode GE in the thickness direction and may be insulated from the gate electrode GE by the gate insulating layer GI. The source electrode SE and the drain electrode DE may be formed by the material of the semiconductor region ACT being conductive.

The gate electrode GE may be disposed on the gate insulating layer Gl. The gate electrode GE may overlap the semiconductor region ACT with the gate insulating layer GI interposed therebetween.

The gate insulating layer GI may be disposed on the semiconductor regions ACT, the source electrodes SE, the drain electrodes DE, and the second buffer layer BF2. The gate insulating layer GI may insulate the semiconductor regions ACT from the gate electrodes GE.

The first interlayer insulating layer ILD1 may be disposed on the gate electrodes GE and the gate insulating layer GI. The first interlayer insulating layer ILD1 may insulate the gate electrodes GE from the capacitor electrodes CPE.

The capacitor electrodes CPE may be disposed on the first interlayer insulating layer ILD1. The capacitor electrodes CPE may overlap the gate electrodes GE in the thickness direction. The capacitor electrodes CPE and the gate electrodes GE may form capacitors.

The second interlayer insulating layer ILD2 may be disposed on the capacitor electrodes CPE and the first interlayer insulating layer ILD1. The second interlayer insulating layer ILD2 may insulate the capacitor electrodes CPE from the first connection electrodes CNE1.

The first connection electrodes CNE1 may be disposed on the second interlayer insulating layer ILD2. The first connection electrodes CNE1 may electrically connect the drain electrodes DE of the thin-film transistors TFT to the second connection electrodes CNE2. The first connection electrodes CNE1 may be inserted in contact holes provided in the second interlayer insulating layer ILD2, the first interlayer insulating layer ILD1 and the gate insulating layer GI to contact the drain electrodes DE of the thin-film transistors TFT.

The first passivation layer PAS1 may be disposed on the first connection electrodes CNE1 and the second interlayer insulating layer ILD2. The first passivation layer PAS1 may protect the thin-film transistors TFT. The first passivation layer PAS1 may insulate the first connection electrodes CNE1 and the second connection electrodes CNE2.

The second connection electrodes CNE2 may be disposed on the first passivation layer PAS1. A second connection electrode CNE2 may electrically connect a first connection electrode CNE1 to a first pixel electrode AE1 of a first light emitting element ED1. The second connection electrodes CNE2 may be inserted in contact holes provided in the first passivation layer PAS1 to contact the first connection electrodes CNE1.

The second passivation layer PAS2 may be disposed on the second connection electrodes CNE2 and the first passivation layer PAS1. The second passivation layer PAS2 may insulate the second connection electrodes CNE2 and the first pixel electrode AE1.

The light emitting element layer EML may be disposed on the thin-film transistor layer TFTL. The light emitting element layer EML may include first to third light emitting elements ED1, ED2, ED3, residual patterns RP, a first insulating layer IL1, an etch control layer EST, capping layers CAP, a conductive layer MTL, a bank BNK, first to third organic patterns ELP1, ELP2, ELP3, first to third electrode patterns CEP1, CEP2, CEP3, first to third capping patterns CLP1, CLP2, CLP3, and first to third inorganic layers TL1, TL2, TL3.

The display device 10 may include a plurality of pixels arranged along a plurality of rows and a plurality of columns in the display area DA. The pixels may respectively include first to third emission areas EA1, EA2, EA3 defined by the bank BNK or the pixel defining layer and may emit light having a peak wavelength (e.g., a predetermined peak wavelength) through the first to third emission areas EA1, EA2, EA3. Each of the first to third emission areas EA1, EA2, EA3 may be an area where light generated by a light emitting element of the display device 10 is emitted to an outside of the display device 10.

Each of the first to third emission areas EA1, EA2, EA3 may emit light having a peak wavelength (e.g., a predetermined peak wavelength) to the outside of the display device 10. The first emission area EA1 may emit light of a first color, the second emission area EA2 may emit light of a second color, and the third emission area EA3 may emit light of a third color. For example, the light of the first color may be red light having a peak wavelength of about 610 to 650 nm, the light of the second color may be green light having a peak wavelength of about 510 to 550 nm, and the light of the third color may be blue light having a peak wavelength of about 440 to 480 nm. However, the present disclosure is not limited thereto.

In an embodiment, for example, an area of the third emission area EA3 may be larger than an area of the first emission area EA1, and the area of the first emission area EA1 may be larger than an area of the second emission area EA2. However, the present disclosure is not limited thereto. As another example, the area of the first emission area EA1, the area of the second emission area EA2, and the area of the third emission area EA3 may be substantially the same.

The first light emitting element ED1 may be disposed on the thin-film transistor layer TFTL in the first emission area EA1. The first light emitting element

ED1 may include the first pixel electrode AE1, a first light emitting layer EL1, and a first common electrode CE1. The second light emitting element ED2 may be disposed on the thin-film transistor layer TFTL in the second emission area EA2. The second light emitting element ED2 may include a second pixel electrode AE2, a second light emitting layer EL2, and a second common electrode CE2. The third light emitting element ED3 may be disposed on the thin-film transistor layer TFTL in the third emission area EA3. The third light emitting element ED3 may include a third pixel electrode AE3, a third light emitting layer EL3, and a third common electrode CE3.

The first to third pixel electrodes AE1, AE2, AE3 may be disposed on the second passivation layer PAS2. Each of the first to third pixel electrodes AE1, AE2, AE3 may be electrically connected to the drain electrode DE of a thin-film transistor TFT through the first and second connection electrodes CNE1 and CNE2. The first to third pixel electrodes AE1, AE2, AE3 may be insulated from each other by the first insulating layer IL1. For example, the first to third pixel electrodes AE1, AE2, AE3 may include at least one of silver (Ag), copper (Cu), aluminum (Al), nickel (Ni), and lanthanum (La). As another example, the first to third pixel electrodes AE1, AE2, AE3 may include a material such as indium tin oxide (ITO), indium zinc oxide (IZO), or indium tin zinc oxide (ITZO). As another example, the first to third pixel electrodes AE1, AE2, AE3 may have a stacked structure of ITO/Ag/ITO, ITO/Ag/IZO, or ITO/Ag/ITZO/IZO.

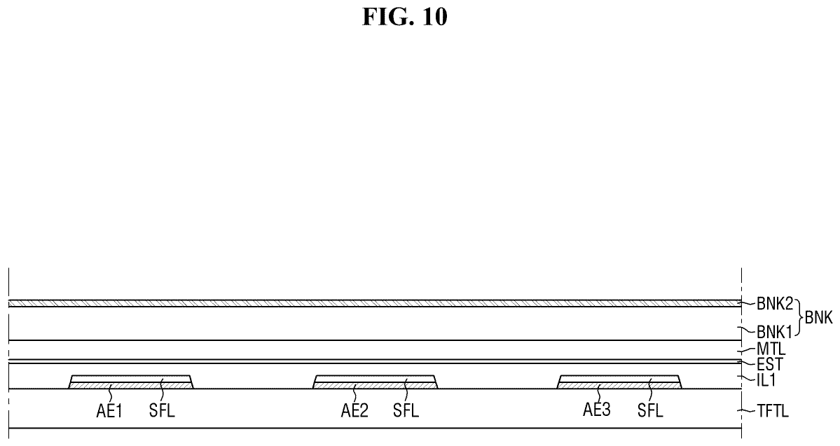

Residual patterns RP may be disposed on edges of each of the first to third pixel electrodes AE1, AE2, AE3. The first insulating layer IL1 may not directly contact an upper surface of each of the first to third pixel electrodes AE1, AE2, AE3 due to the residual patterns RP. The residual patterns RP may be formed as a result of removing a sacrificial layer SFL (see FIG. 10) on each of the first to third pixel electrodes AE1, AE2, AE3 in a process of manufacturing the display device 10.

The first insulating layer IL1 may be disposed on the second passivation layer PAS2 and the residual patterns RP. The first insulating layer IL1 may cover the edges of the first to third pixel electrodes AE1, AE2, AE3 and the residual patterns RP and may partially expose the upper surfaces of the first to third pixel electrodes AE1, AE2, AE3. For example, the first insulating layer IL1 may expose the first pixel electrode AE1 in the first emission area EA1, and the first light emitting layer EL1 may be directly disposed on the first pixel electrode AE1. In an embodiment, the first insulating layer IL1 may include an inorganic insulating material. The first insulating layer IL1 may include, but is not limited to, at least one of a silicon nitride layer, a silicon oxynitride layer, a silicon oxide layer, a titanium oxide layer, an aluminum oxide layer, and an amorphous silicon layer.

The etch control layer EST may be disposed on the first insulating layer IL1. The etch control layer EST may function as an etching stopper. The etch control layer EST may protect the first to third pixel electrodes AE1, AE2, AE3 during a process of etching the bank BNK and the conductive layer MTL. Optionally, the etch control layer EST may be omitted.

The first to third light emitting layers EL1, EL2, EL3 may be organic light emitting layers made of an organic material and may be respectively formed on the first to third pixel electrodes AE1, AE2, AE3 through a deposition process. For example, an organic material may be deposited in a direction inclined from an upper surface of the substrate SUB in a deposition process of the first to third light emitting layers EL1, EL2, EL3.

The first light emitting layer EL1 may be directly disposed on the first pixel electrode AE1 in the first emission area EA1. A portion of the first light emitting layer EL1 may fill a space around (e.g., surrounded by) the first pixel electrode AE1, the residual patterns RP, and the first insulating layer IL1, and another portion of the first light emitting layer EL1 may cover side surfaces of the etch control layer EST and upper surfaces of edges of the etch control layer EST and side surfaces of the first insulating layer IL1. The second light emitting layer EL2 may be directly disposed on the second pixel electrode AE2 in the second emission area EA2. A portion of the second light emitting layer EL2 may fill a space around (e.g., surrounded by) the second pixel electrode AE2, the residual patterns RP, and the first insulating layer IL1, and another portion of the second light emitting layer EL2 may cover the side surfaces of the etch control layer EST and the upper surfaces of the edges of the etch control layer EST and the side surfaces of the first insulating layer IL1. The third light emitting layer EL3 may be directly disposed on the third pixel electrode AE3 in the third emission area EA3. A portion of the third light emitting layer EL3 may fill a space around (e.g., surrounded by) the third pixel electrode AE3, the residual patterns RP and the first insulating layer IL1, and another portion of the third light emitting layer EL3 may cover the side surfaces of the etch control layer EST and the upper surfaces of the edges of the etch control layer EST and the side surfaces of the first insulating layer IL1.

The first common electrode CE1 may be disposed on the first light emitting layer EL1, the second common electrode CE2 may be disposed on the second light emitting layer EL2, and the third common electrode CE3 may be disposed on the third light emitting layer EL3. The first to third common electrodes CE1, CE2, CE3 may include a transparent conductive material and transmit light generated from the first to third light emitting layers EL1, EL2, EL3. The first to third common electrodes CE1, CE2, CE3 may contact side surfaces of the conductive layer MTL and upper surfaces of edges of the conductive layer MTL. The first to third common electrodes CE1, CE2, CE3 may be electrically connected by the conductive layer MTL. For example, the first common electrode CE1 may receive a common voltage, a cathode voltage, or a low potential voltage.

The first pixel electrode AE1 may receive a voltage corresponding to a data voltage from a thin-film transistor TFT, and the first common electrode CE1 may receive a common voltage, a cathode voltage, or a low potential voltage. In this case, a potential difference is formed between the first pixel electrode AE1 and the first common electrode CE1, such that holes may move to the first light emitting layer EL1 through a hole transporting layer, and electrons may move to the first light emitting layer EL1 through an electron transporting layer. Accordingly, the first light emitting layer EL1 may emit light.

The capping layers CAP may be disposed on the first to third common electrodes CE1, CE2, CE3 in the first to third emission areas EA1, EA2, EA3. In an embodiment, the capping layers CAP may include an inorganic insulating material and may cover the first to third light emitting elements ED1, ED2, ED3. The capping layers CAP may prevent or substantially prevent the first to third light emitting elements ED1, ED2, ED3 from being damaged by external air. For example, the capping layers CAP may include, but are not limited to, at least one of a silicon nitride layer, a silicon oxynitride layer, a silicon oxide layer, a titanium oxide layer, an aluminum oxide layer, and an amorphous silicon layer.

The conductive layer MTL may be disposed on the etch control layer EST and overlapped by the bank BNK. In an embodiment, the conductive layer MTL may surround the first to third emission areas EA1, EA2, EA3 in a plan view. In an embodiment, the conductive layer MTL may include a metal material with high electrical conductivity. For example, the conductive layer MTL may include, but is not limited to, aluminum (Al). Therefore, the first to third common electrodes CE1, CE2, CE3 may be electrically connected by the conductive layer MTL.

The bank BNK may be disposed on the conductive layer MTL to define the first to third emission areas EA1, EA2, EA3. In an embodiment, the bank BNK may surround the first to third emission areas EA1, EA2, EA3 in a plan view. In an embodiment, the bank BNK may include first and second banks BNK1 and BNK2.

The first bank BNK1 may be disposed on the conductive layer MTL, and the second bank BNK2 may be disposed on the first bank BNK1. Side surfaces of the first bank BNK1 may be recessed inward from side surfaces of the second bank BNK2. Since the side surfaces of the second bank BNK2 protrude from the side surfaces of the first bank BNK1 toward the first emission area EA1, the second bank BNK2 may include protruding tips. Accordingly, an undercut structure may be formed under each tip of the second bank BNK2. In an embodiment, a thickness of the first bank BNK1 may be greater than a thickness of the second bank BNK2.

In an embodiment, the first and second banks BNK1 and BNK2 may include different metal materials. An etching rate of the first bank BNK1 and an etching rate of the second bank BNK2 may be different from each other. For example, the etching rate of the first bank BNK1 may be greater than that of the second bank BNK2 in a wet etching process, and the first bank BNK1 may be etched more than the second bank BNK2 in the process of forming the first to third emission areas EA1, EA2, EA3. Therefore, the side shape of the first and second banks BNK1 and BNK2 may be determined by a difference in etching rate between the first and second banks BNK1 and BNK2. The first bank BNK1 may include a metal material having high electrical conductivity, and the second bank BNK2 may include a material having low reflectivity. For example, the first bank BNK1 may include aluminum (Al), and the second bank BNK2 may include titanium (Ti). However, the present disclosure is not limited thereto.

The first and second banks BNK1 and BNK2 may include a groove GRV recessed from an upper surface of the bank BNK. The groove GRV may penetrate from the second bank BNK2 to a portion of the first bank BNK1. In a plan view, the groove GRV may be spaced apart from the first to third emission areas EA1, EA2, and EA3 with the second bank BNK2 therebetween. The groove GRV may accommodate first to third organic patterns ELP1, ELP2, ELP3, first to third electrode patterns CEP1, CEP2, CEP3, and first to third capping patterns CLP1, CLP2, CLP3. For example, a depth of the groove GRV may be greater than a sum of a thickness of the first organic pattern ELP1, a thickness of the first electrode pattern CEP1, and a thickness of the first capping pattern CLP1, but is not limited thereto.

The bank BNK may form the first to third emission areas EA1, EA2, EA3 through a mask process, and the first to third light emitting layers EL1, EL2, EL3 may be formed in the first to third emission areas EA1, EA2, EA3, respectively. When a mask process is performed, a structure for supporting a mask may be required, and an excessively wide non-display area NDA may be required to control dispersion of the mask process. Therefore, if the mask process is minimized, a structure for supporting a mask can be omitted, and the area of the non-display area NDA for dispersion control can be minimized or reduced.

In an embodiment, the first to third light emitting elements ED1, ED2, ED3 may be formed through deposition and etching processes rather than a mask process. In an embodiment, the first and second banks BNK1 and BNK2 include different metal materials, and each inner wall of the bank BNK may have a tip structure. In the display device 10, different layers may be individually formed in the first to third emission areas EA1, EA2, EA3 through a deposition process. For example, the first light emitting layer EL1 and the first organic pattern ELP1 may be deposited using a same organic material in a deposition process without a mask and may be cut and separated by the tips formed on the inner walls of the bank BNK. The first light emitting layer EL1 may be disposed in the first emission area EA1, and the first organic pattern ELP1 may be disposed on the bank BNK adjacent to the first emission area EA1.

In an embodiment, an organic material for forming the first light emitting layer EL1 may be deposited on an entire surface of the display device 10, and the organic material of the first light emitting layer EL1 deposited in the second and third emission areas EA2 and EA3 may be removed. In an embodiment, an organic material for forming the second light emitting layer EL2 may be deposited on an entire surface of the display device 10, and the organic material of the second light emitting layer EL2 deposited in the first and third emission areas EA1 and EA3 may be removed. In an embodiment, an organic material for forming the third light emitting layer EL3 may be deposited on an entire surface of the display device 10, and the organic material of the third light emitting layer EL3 deposited in the first and second emission areas EA1 and EA2 may be removed. Therefore, in the display device 10, different organic materials can be formed in the first to third emission areas EA1, EA2, EA3 through deposition and etching processes without using a mask process. The display device 10 can reduce manufacturing costs by omitting unnecessary processes and can minimize or reduce an area of the non-display area NDA.

In an embodiment, the first organic pattern ELP1 may include a same organic material as the first light emitting layer EL1. A portion of the first organic pattern ELP1 may be disposed on the second bank BNK2 adjacent to the first emission area EA1, and another portion of the first organic pattern ELP1 may be accommodated in the groove GRV. In an embodiment, the first light emitting layer EL1 and the first organic pattern ELP1 may be deposited in a same process and may be cut and separated by tips of the second bank BNK2. Accordingly, the first organic pattern ELP1 may be disposed on the second bank BNK2 in an area adjacent to the first emission area EA1.

In an embodiment, the first electrode pattern CEP1 may include a same metal material as the first common electrode CE1 and may be disposed on the first organic pattern ELP1. A portion of the first electrode pattern CEP1 may be disposed on the first organic pattern ELP1 on the second bank BNK2 and another portion of the first electrode pattern CEP1 may be disposed on the first organic pattern ELP1 in the groove GRV. In an embodiment, the first common electrode CE1 and the first electrode pattern CEP1 may be deposited in a same process and may be cut and separated by the tips of the second bank BNK2. Accordingly, the first electrode pattern CEP1 may be disposed on the first organic pattern ELP1 in the area adjacent to the first emission area EA1.

In an embodiment, the first capping pattern CLP1 may include a same inorganic material as the capping layer CAP and may be disposed on the first electrode pattern CEP1. A portion of the first capping pattern CLP1 may be disposed on the first electrode pattern CEP1 on the second bank BNK2 and another portion of the first capping pattern CLP1 may be disposed on first electrode pattern CEP1 in the groove GRV. In an embodiment, the capping layer CAP and the first capping pattern CLP1 may be deposited in a same process and may be cut and separated by the tips of the second bank BNK2. Accordingly, the first capping pattern CLP1 may be disposed on the first electrode pattern CEP1 in the area adjacent to the first emission area EA1.

The first inorganic layer TL1 may be disposed on the capping layer CAP of the first emission area EA1 and the first capping pattern CLP1. The first inorganic layer TL1 may cover an upper surface of the capping layer CAP in the first emission area EA1. The first inorganic layer TL1 may cover the side surfaces of the first bank BNK1, lower and side surfaces of the tips of the second bank BNK2, the side surfaces of the first organic pattern ELP1, side surfaces of the first electrode pattern CEP1, and upper and side surfaces of the first capping pattern CLP1 disposed on the second bank BNK2. The first inorganic layer TL1 may cover the upper surface of the first capping pattern CLP1 in the groove GRV. The first inorganic layer TL1 may include an inorganic material to prevent or substantially prevent oxygen or moisture from penetrating into the first light emitting element ED1. The first inorganic layer TL1 may be an inorganic encapsulation layer. For example, the first inorganic layer TL1 may include, but is not limited to, at least one of a silicon nitride layer, a silicon oxynitride layer, a silicon oxide layer, a titanium oxide layer, an aluminum oxide layer, and an amorphous silicon layer.

The display device 10 may accommodate a portion of the first organic pattern ELP1, a portion of the first electrode pattern CEP1, and a portion of the first capping pattern CLP1 by including the groove GRV, and the first inorganic layer TL1 may cover side surfaces of the first organic pattern ELP1, the first electrode pattern CEP1, and the first capping pattern CLP1 disposed on the second bank BNK2. The first inorganic layer TL1 may not cover the side surfaces of the first organic pattern ELP1, the first electrode pattern CEP1, and the first capping pattern CLP1 accommodated in the groove GRV, but moisture penetration through the first organic pattern ELP1, the first electrode pattern CEP1, and the first capping pattern CLP1 accommodated in the groove GRV may be blocked by the groove GRV and the first light emitting element ED1 may not be affected. Accordingly, the display device 10 can block the moisture permeation path passing through the first organic pattern ELP1, the first electrode pattern CEP1, and the first capping pattern CLP1, and the reliability of the first light emitting element ED1 can be improved.

In an embodiment, the second organic pattern ELP2 may include a same organic material as the second light emitting layer EL2. A portion of the second organic pattern ELP2 may be disposed on the second bank BNK2 adjacent to the second emission area EA2, and another portion of the second organic pattern ELP2 may be accommodated in the groove GRV. In an embodiment, the second light emitting layer EL2 and the second organic pattern ELP2 may be deposited in a same process and may be cut and separated by tips of the second bank BNK2. Accordingly, the second organic pattern ELP2 may be disposed on the second bank BNK2 in an area adjacent to the second emission area EA2.

In an embodiment, the second electrode pattern CEP2 may include a same metal material as the second common electrode CE2 and may be disposed on the second organic pattern ELP2. A portion of the second electrode pattern CEP2 may be disposed on the second organic pattern ELP2 on the second bank BNK2, and another portion of the second electrode pattern CEP2 may be disposed on the second organic pattern ELP2 in the groove GRV. In an embodiment, the second common electrode CE2 and the second electrode pattern CEP2 may be deposited in a same process and may be cut and separated by the tips of the second bank BNK2. Accordingly, the second electrode pattern CEP2 may be disposed on the second organic pattern ELP2 in the area adjacent to the second emission area EA2.

In an embodiment, the second capping pattern CLP2 may include a same inorganic material as the capping layer CAP and may be disposed on the second electrode pattern CEP2. A portion of the second capping pattern CLP2 may be disposed on the second electrode pattern CEP2 on the second bank BNK2, and another portion of the second capping pattern CLP2 may be disposed on the second electrode pattern CEP2 in the groove GRV. In an embodiment, the capping layer CAP and the second capping pattern CLP2 may be deposited in a same process and may be cut and separated by the tips of the second bank BNK2. Accordingly, the second capping pattern CLP2 may be disposed on the second electrode pattern CEP2 in the area adjacent to the second emission area EA2.

The second inorganic layer TL2 may be disposed on the capping layer CAP of the second emission area EA2 and the second capping pattern CLP2. The second inorganic layer TL2 may cover an upper surface of the capping layer CAP in the second emission area EA2. The second inorganic layer TL2 may cover the side surfaces of the first bank BNK1, the lower and side surfaces of the tips of the second bank BNK2, side surfaces of the second organic pattern ELP2, side surfaces of the second electrode pattern CEP2, and upper and side surfaces of the second capping pattern CLP2 disposed on the second bank BNK2. The second inorganic layer TL2 may cover the upper surface of the second capping pattern CLP2 in the groove GRV. The second inorganic layer TL2 may include an inorganic material to prevent or substantially prevent oxygen or moisture from penetrating into the second light emitting element ED2. The second inorganic layer TL2 may be an inorganic encapsulation layer. For example, the second inorganic layer TL2 may be made of at least one of the materials described as an example with respect to the first inorganic layer TL1.

The display device 10 may accommodate a portion of the second organic pattern ELP2, a portion of the second electrode pattern CEP2, and a portion of the second capping pattern CLP2 by including the groove GRV, and the second inorganic layer TL2 may cover side surfaces of the second organic pattern ELP2, the second electrode pattern CEP2, and the second capping pattern CLP2 disposed on the second bank BNK2. The second inorganic layer TL2 may not cover the side surfaces of the second organic pattern ELP2, the second electrode pattern CEP2, and the second capping pattern CLP2 accommodated in the groove GRV, but moisture penetration through the second organic pattern ELP2, the second electrode pattern CEP2, and the second capping pattern CLP2 accommodated in the groove GRV may be blocked by the groove GRV, and the second light emitting element ED2 may not be affected. Accordingly, the display device 10 can block the moisture permeation path passing through the second organic pattern ELP2, the second electrode pattern CEP2, and the second capping pattern CLP2, and the reliability of the second light emitting element ED2 can be improved.

In an embodiment, the third organic pattern ELP3 may include a same organic material as the third light emitting layer EL3. A portion of the third organic pattern ELP3 may be disposed on the second bank BNK2 adjacent to the third emission area EA3, and another portion of the third organic pattern ELP3 may be accommodated in the groove GRV. In an embodiment, the third light emitting layer EL3 and the third organic pattern ELP3 may be deposited in a same process and may be cut and separated by tips of the second bank BNK2. Accordingly, the third organic pattern ELP3 may be disposed on the second bank BNK2 in an area adjacent to the third emission area EA3.

In an embodiment, the third electrode pattern CEP3 may include a same metal material as the third common electrode CE3 and may be disposed on the third organic pattern ELP3. A portion of the third electrode pattern CEP3 may be disposed on the third organic pattern ELP3 on the second bank BNK2, and another portion of the third electrode pattern CEP3 may be disposed on the third organic pattern ELP3 in the groove GRV. In an embodiment, the third common electrode CE3 and the third electrode pattern CEP3 may be deposited in a same process and may be cut and separated by the tips of the second bank BNK2. Accordingly, the third electrode pattern CEP3 may be disposed on the third organic pattern ELP3 in the area adjacent to the third emission area EA3.

In an embodiment, the third capping pattern CLP3 may include a same inorganic material as the capping layer CAP and may be disposed on the third electrode pattern CEP3. A portion of the third capping pattern CLP3 may be disposed on the third electrode pattern CEP3 on the second bank BNK2, and another portion of the third capping pattern CLP3 may be disposed on the third electrode pattern CEP3 in the groove GRV. In an embodiment, the capping layer CAP and the third capping pattern CLP3 may be deposited in a same process and may be cut and separated by the tips of the second bank BNK2. Accordingly, the third capping pattern CLP3 may be disposed on the third electrode pattern CEP3 in the area adjacent to the third emission area EA3.

The third inorganic layer TL3 may be disposed on the capping layer CAP of the third emission area EA3 and the third capping pattern CLP3. The third inorganic layer TL3 may cover an upper surface of the capping layer CAP in the third emission area EA3. The third inorganic layer TL3 may cover the side surfaces of the first bank BNK1, the lower and side surfaces of the tips of the second bank BNK2, side surfaces of the third organic pattern ELP3, side surfaces of the third electrode pattern CEP3, and upper and side surfaces of the third capping pattern CLP3 disposed on the second bank BNK2. The third inorganic layer TL3 may cover the upper surface of the third capping pattern CLP3 in the groove GRV. The third inorganic layer TL3 may include an inorganic material to prevent or substantially prevent oxygen or moisture from penetrating into the third light emitting element ED3. The third inorganic layer TL3 may be an inorganic encapsulation layer. For example, the third inorganic layer TL3 may be made of at least one of the materials described as an example of the first inorganic layer TL1.

The display device 10 may accommodate a portion of the third organic pattern ELP3, a portion of the third electrode pattern CEP3, and a portion of the third capping pattern CLP3 by including the groove GRV, and the third inorganic layer TL3 may cover side surfaces of the third organic pattern ELP3, the third electrode pattern CEP3, and the third capping pattern CLP3 disposed on the second bank BNK2. The third inorganic layer TL3 may not cover the side surfaces of the third organic pattern ELP3, the third electrode pattern CEP3, and the third capping pattern CLP3 accommodated in the groove GRV, but moisture penetration through the third organic pattern ELP3, the third electrode pattern CEP3, and the third capping pattern CLP3 accommodated in the groove GRV may be blocked by the groove GRV, and the third light emitting element ED3 may not be affected. Accordingly, the display device 10 can block the moisture permeation path passing through the third organic pattern ELP3, the third electrode pattern CEP3, and the third capping pattern CLP3, and the reliability of the third light emitting element ED3 can be improved.

The encapsulation layer TFEL may be disposed on the first to third inorganic layers TL1, TL2, TL3 to cover the light emitting element layer EML. The encapsulation layer TFEL may include first to third encapsulation layers TFE1 through TFE3.

The first encapsulation layer TFE1 may be disposed on the first to third inorganic layers TL1, TL2, TL3. The first encapsulation layer TFE1 may include an inorganic material to prevent or substantially prevent oxygen or moisture from penetrating into the light emitting element layer EML. For example, the first encapsulation layer TFE1 may include, but is not limited to, at least one of a silicon nitride layer, a silicon oxynitride layer, a silicon oxide layer, a titanium oxide layer, an aluminum oxide layer, and an amorphous silicon layer.

The second encapsulation layer TFE2 may be disposed on the first encapsulation layer TFE1 to planarize the top of the light emitting element layer EML. The second encapsulation layer TFE2 may include an organic material to protect the light emitting element layer EML from foreign substances, such as dust. For example, the second encapsulation layer TFE2 may include an organic material, such as acryl resin, epoxy resin, phenolic resin, polyamide resin, or polyimide resin. The second encapsulation layer TFE2 may be formed by curing a monomer or applying a polymer.

The third encapsulation layer TFE3 may be disposed on the second encapsulation layer TFE2. The third encapsulation layer TFE3 may include an inorganic material to prevent or substantially prevent oxygen or moisture from penetrating into the light emitting element layer EML. For example, the third encapsulation layer TFE3 may be made of at least one of the materials described as an example of the first encapsulation layer TFE1.

The touch sensing unit TSU may be disposed on the encapsulation layer TFEL. The touch sensing unit TSU may include a third buffer layer BF3, a bridge electrode BRG, a second insulating layer IL2, touch electrodes TE, and a third insulating layer IL3.

The third buffer layer BF3 may be disposed on the encapsulation layer TFEL. The third buffer layer BF3 may have insulating and optical functions. The third buffer layer BF3 may include at least one inorganic layer. Optionally, the third buffer layer BF3 may be omitted.

The bridge electrode BRG may be disposed on the third buffer layer BF3. The bridge electrode BRG may be disposed on a different layer from the touch electrodes TE and may electrically connect adjacent touch electrodes TE.

The second insulating layer IL2 may be disposed on the bridge electrode BRG and the third buffer layer BF3. The second insulating layer IL2 may have insulating and optical functions. For example, the second insulating layer IL2 may include, but is not limited to, at least one of a silicon nitride layer, a silicon oxynitride layer, a silicon oxide layer, a titanium oxide layer, an aluminum oxide layer, and an amorphous silicon layer.

The touch electrodes TE may be disposed on the second insulating layer IL2. The touch electrodes TE may include driving electrodes and sensing electrodes and sense a change in mutual capacitance between the driving electrodes and the sensing electrodes. In an embodiment, the touch electrodes TE may not overlap the first to third emission areas EA1, EA2, EA3. Each of the touch electrodes TE may be a single layer of molybdenum (Mo), titanium (Ti), copper (Cu), aluminum (Al) or indium tin oxide (ITO) or may be a stacked structure (Ti/Al/Ti) of aluminum and titanium, a stacked structure (ITO/Al/ITO) of aluminum and indium tin oxide, an APC alloy, or a stacked structure (ITO/APC/ITO) of an APC alloy and indium tin oxide.

The third insulating layer IL3 may be disposed on the touch electrodes TE and the second insulating layer IL2. The third insulating layer IL3 may have insulating and optical functions. The third insulating layer IL3 may be made of at least one of the materials described as an example of the second insulating layer IL2.

The color filter layer CFL may be disposed on the touch sensing unit TSU. The color filter layer CFL may include a light blocking member BM, first to third color filters CF1, CF2, CF3, and a planarization layer OC.

The light blocking member BM may be disposed on the third insulating layer IL3 around (e.g., to surround) first to third optical areas OPT1 to OPT3. The light blocking member BM may overlap the touch electrodes TE. The light blocking member BM may include a light absorbing material to prevent or substantially prevent reflection of light. For example, the light blocking member BM may include an inorganic black pigment, an organic black pigment, or an organic blue pigment. The inorganic black pigment may be carbon black or a metal oxide, such as titanium black, the organic black pigment may include at least one of lactam black, perylene black and aniline black, and the organic blue pigment may be C.I pigment blue. However, the present disclosure is not limited thereto. The light blocking member BM may prevent or substantially prevent color mixing by preventing or substantially preventing intrusion of visible light between the first to third emission areas EA1, EA2, EA3, thereby improving a color gamut of the display device 10.

The first to third color filters CF1, CF2, CF3 may be disposed on the third insulating layer IL3 to correspond to the first to third emission areas EA1, EA2, EA3, respectively.

The first color filter CF1 may be disposed on the third insulating layer IL3 in the first emission area EA1. In an embodiment, the first color filter CF1 may be surrounded by the light blocking member BM in a plan view. Edges of the first color filter CF1 may partially cover an upper surface of the light blocking member BM, but the present disclosure is not limited thereto. The first color filter CF1 may selectively transmit light of the first color (e.g., red light) and block or absorb light of the second color (e.g., green light) and light of the third color (e.g., blue light). For example, the first color filter CF1 may be a red color filter and may include a red colorant.

The second color filter CF2 may be disposed on the third insulating layer IL3 in the second emission area EA2. In an embodiment, the second color filter CF2 may be surrounded by the light blocking member BM in a plan view. Edges of the second color filter CF2 may partially cover the upper surface of the light blocking member BM, but the present disclosure is not limited thereto. The second color filter CF2 may selectively transmit light of the second color (e.g., green light) and block or absorb light of the first color (e.g., red light) and light of the third color (e.g., blue light). For example, the second color filter CF2 may be a green color filter and may include a green colorant.

The third color filter CF3 may be disposed on the third insulating layer IL3 in the third emission area EA3. In an embodiment, the third color filter CF3 may be surrounded by the light blocking member BM in a plan view. Edges of the third color filter CF3 may partially cover the upper surface of the light blocking member BM, but the present disclosure is not limited thereto. The third color filter CF3 may selectively transmit light of the third color (e.g., blue light) and block or absorb light of the first color (e.g., red light) and light of the second color (e.g., green light). For example, the third color filter CF3 may be a blue color filter and may include a blue colorant.

The first to third color filters CF1, CF2, CF3 may absorb a part of light coming from the outside of the display device 10, thereby reducing reflected light caused by the external light. Therefore, the first to third color filters CF1, CF2, CF3 can prevent or substantially prevent color distortion caused by reflection of external light.

The planarization layer OC may be disposed on the light blocking member BM and the first to third color filters CF1, CF2, CF3. The planarization layer OC may planarize the top of the color filter layer CFL. For example, the planarization layer OC may include an organic insulating material.

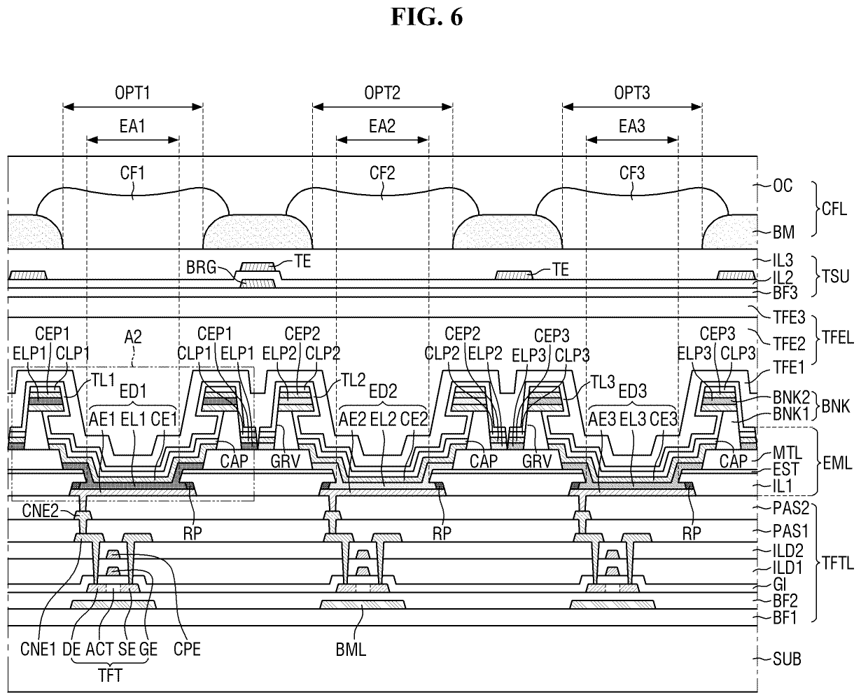

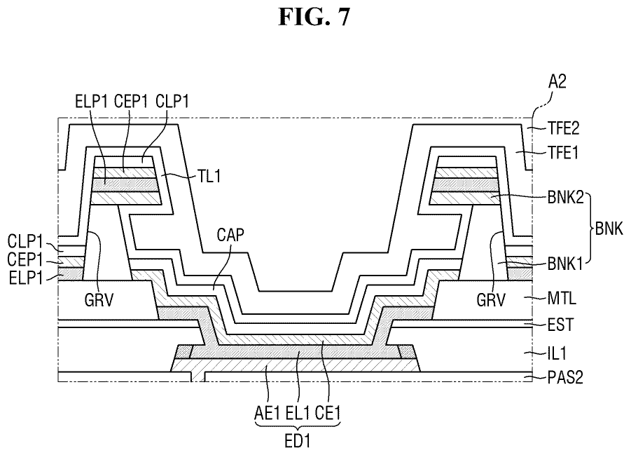

FIG. 6 is a cross-sectional view illustrating pixels of a display device according to an embodiment; and FIG. 7 is an enlarged view of a region “A2” of FIG. 6. The display device 10 of FIGS. 6 and 7 is different from the display device 10 of FIGS. 4 and 5 in the configuration of a groove GRV. The same elements as those described above may be briefly described or may not be described.

Referring to FIGS. 6 and 7, a display panel 100 may include a display unit DU, a touch sensing unit TSU, and a color filter layer CFL. The display unit DU may include a substrate SUB, a thin-film transistor layer TFTL, a light emitting element layer EML, and an encapsulation layer TFEL.

The light emitting element layer EML may be disposed on the thin-film transistor layer TFTL. The light emitting element layer EML may include first to third light emitting elements ED1, ED2, ED3, residual patterns RP, a first insulating layer IL1, an etch control layer EST, capping layers CAP, a conductive layer MTL, the bank BNK, first to third organic patterns ELP1, ELP2, ELP3, first to third electrode patterns CEP1, CEP2, CEP3, first to third capping patterns CLP1, CLP2, CLP3, and first to third inorganic layers TL1, TL2, TL3.

The conductive layer MTL may be disposed on the first insulating layer IL1 and overlap the bank BNK. In an embodiment, the conductive layer MTL may surround the first to third emission areas EA1, EA2, EA3 in a plan view. In an embodiment, the conductive layer MTL may include a metal material with high electrical conductivity. For example, the conductive layer MTL may include aluminum (Al), but is not limited thereto. Accordingly, the first to third common electrodes CE1, CE2, CE3 may be electrically connected by the conductive layer MTL.

The bank BNK may be disposed on the conductive layer MTL to define first to third emission areas EA1, EA2, EA3. In an embodiment, the bank BNK may surround the first to third emission areas EA1, EA2, EA3 in a plan view. The bank BNK may include first and second banks BNK1 and BNK2.

The first and second banks BNK1 and BNK2 may include a groove GRV recessed from an upper surface of the bank BNK. The groove GRV may penetrate from the upper surface of the second bank BNK2 to the lower surface of the first bank BNK1 to expose the upper surface of the conductive layer MTL. In a plan view, the groove GRV may be spaced apart from the first to third emission areas EA1, EA2, EA3 with the second bank BNK2 therebetween. The groove GRV may accommodate first to third organic patterns ELP1, ELP2, ELP3, first to third electrode patterns CEP1, CEP2, CEP3, and first to third capping patterns CLP1, CLP2, CLP3. For example, a depth of the groove GRV may be greater than a sum of a thickness of the first organic pattern ELP1, a thickness of the first electrode pattern CEP1, and a thickness of the first capping pattern CLP1, but is not limited thereto.

In an embodiment, the first organic pattern ELP1 may include a same organic material as the first light emitting layer EL1. A portion of the first organic pattern ELP1 may be disposed on the second bank BNK2 adjacent to the first emission area EA1, and another portion of the first organic pattern ELP1 may be accommodated in the groove GRV to be directly disposed on the conductive layer MTL. In an embodiment, the first light emitting layer EL1 and the first organic pattern ELP1 may be deposited in a same process and may be cut and separated by tips of the second bank BNK2. Accordingly, the first organic pattern ELP1 may be disposed on the second bank BNK2 in an area adjacent to the first emission area EA1.

The display device 10 may accommodate a portion of the first organic pattern ELP1, a portion of the first electrode pattern CEP1, and a portion of the first capping pattern CLP1 by including the groove GRV, and the first inorganic layer TL1 may cover side surfaces of the first organic pattern ELP1, the first electrode pattern CEP1, and the first capping pattern CLP1 disposed on the second bank BNK2. In an embodiment, the first inorganic layer TL1 may not cover the side surfaces of the first organic pattern ELP1, the first electrode pattern CEP1, and the first capping pattern CLP1 accommodated in the groove GRV, but moisture penetration through the first organic pattern ELP1, the first electrode pattern CEP1, and the first capping pattern CLP1 accommodated in the groove GRV may be blocked by the groove GRV, and the first light emitting element ED1 may not be affected. Accordingly, the display device 10 can block the moisture permeation path passing through the first organic pattern ELP1, the first electrode pattern CEP1, and the first capping pattern CLP1, and the reliability of the first light emitting element ED1 can be improved.

In an embodiment, the second organic pattern ELP2 may include a same organic material as the second light emitting layer EL2. A portion of the second organic pattern ELP2 may be disposed on the second bank BNK2 adjacent to the second emission area EA2, and another portion of the second organic pattern ELP2 may be accommodated in the groove GRV and disposed on the conductive layer MTL. In an embodiment, the second light emitting layer EL2 and the second organic pattern ELP2 may be deposited in the same process and may be cut and separated by tips of the second bank BNK2. Accordingly, the second organic pattern ELP2 may be disposed on the second bank BNK2 in an area adjacent to the second emission area EA2.

The display device 10 may accommodate a portion of the second organic pattern ELP2, a portion of the second electrode pattern CEP2, and a portion of the second capping pattern CLP2 by including the groove GRV, and the second inorganic layer TL2 may cover side surfaces of the second organic pattern ELP2, the second electrode pattern CEP2, and the second capping pattern CLP2 disposed on the second bank BNK2. In an embodiment, the second inorganic layer TL2 may not cover the side surfaces of the second organic pattern ELP2, the second electrode pattern CEP2, and the second capping pattern CLP2 accommodated in the groove GRV, but moisture penetration through the second organic pattern ELP2, the second electrode pattern CEP2, and the second capping pattern CLP2 accommodated in the groove GRV may be blocked by the groove GRV, and the second light emitting element ED2 may not be affected. Accordingly, the display device 10 can block the moisture permeation path passing through the second organic pattern ELP2, the second electrode pattern CEP2, and the second capping pattern CLP2, and the reliability of the second light emitting element ED2 can be improved.

In an embodiment, the third organic pattern ELP3 may include a same organic material as the third light emitting layer EL3. A portion of the third organic pattern ELP3 may be disposed on the second bank BNK2 adjacent to the third emission area EA3, and another portion of the third organic pattern ELP3 may be accommodated in the groove GRV and disposed on the conductive layer MTL. In an embodiment, the third light emitting layer EL3 and the third organic pattern ELP3 may be deposited in a same process and may be cut and separated by tips of the second bank BNK2. Accordingly, the third organic pattern ELP3 may be disposed on the second bank BNK2 in an area adjacent to the third emission area EA3.

The display device 10 may accommodate a portion of the third organic pattern ELP3, a portion of the third electrode pattern CEP3, and a portion of the third capping pattern CLP3 by including the groove GRV, and the third inorganic layer TL3 may cover side surfaces of the third organic pattern ELP3, the third electrode pattern CEP3, and the third capping pattern CLP3 disposed on the second bank BNK2. In an embodiment, the third inorganic layer TL3 may not cover the side surfaces of the third organic pattern ELP3, the third electrode pattern CEP3, and the third capping pattern CLP3 accommodated in the groove GRV, but moisture penetration through the third organic pattern ELP3, the third electrode pattern CEP3, and the third capping pattern CLP3 accommodated in the groove GRV may be blocked by the groove GRV, and the third light emitting element ED3 may not be affected. Accordingly, the display device 10 can block the moisture permeation path passing through the third organic pattern ELP3, the third electrode pattern CEP3, and the third capping pattern CLP3, and the reliability of the third light emitting element ED3 can be improved.

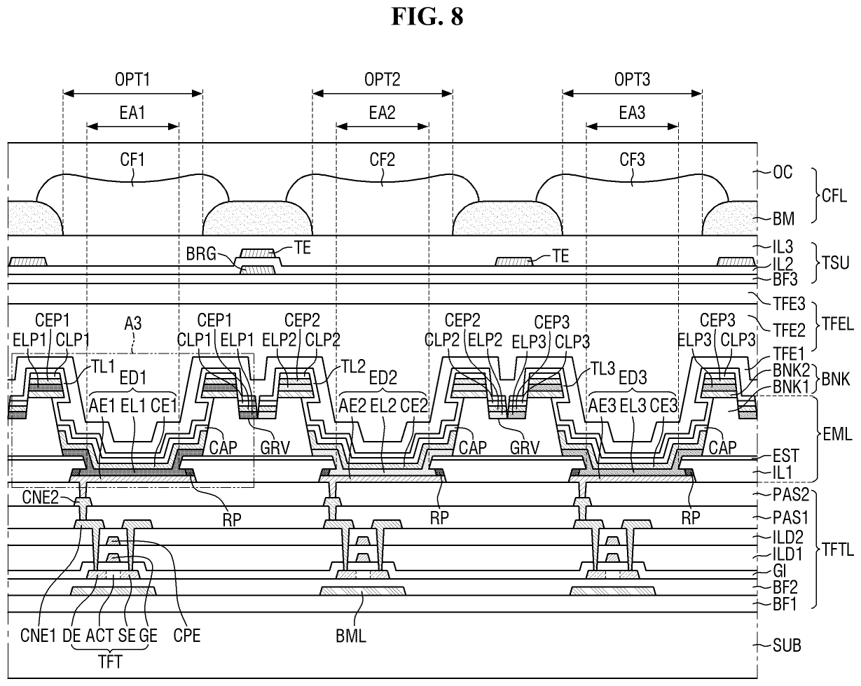

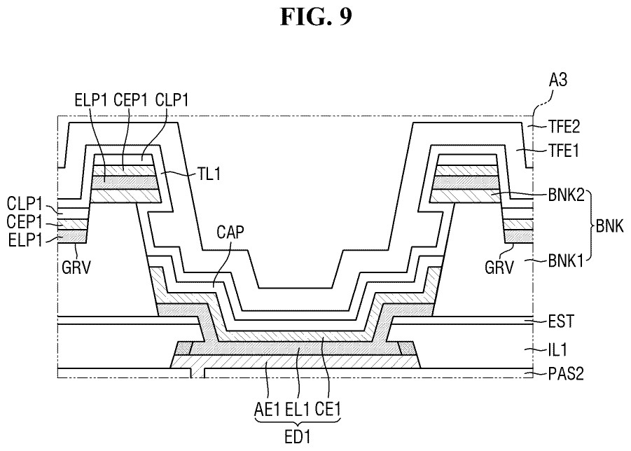

FIG. 8 is a cross-sectional view illustrating pixels of a display device according to an embodiment; and FIG. 9 is an enlarged view of a region “A3” of FIG. 8. The display device 10 of FIGS. 8 and 9 is the display device of FIGS. 4 and 5 in which the conductive layer MTL is omitted. The same elements as those described above may be briefly described or may not be described.

Referring to FIGS. 8 and 9, a display panel 100 may include a display unit DU, a touch sensing unit TSU, and a color filter layer CFL. The display unit DU may include a substrate SUB, a thin-film transistor layer TFTL, a light emitting element layer EML, and an encapsulation layer TFEL.

The light emitting element layer EML may be disposed on the thin-film transistor layer TFTL. The light emitting element layer EML may include first to third light emitting elements ED1, ED2, ED3, residual patterns RP, a first insulating layer IL1, an etch control layer EST, capping layers CAP, the bank BNK, first to third organic patterns ELP1, ELP2, ELP3, first to third electrode patterns CEP1, CEP2, CEP3, first to third capping patterns CLP1, CLP2, CLP3, and first to third inorganic layers TL1, TL2, TL3.

The bank BNK may be disposed on the etch control layer EST to define first to third emission areas EA1, EA2, EA3. In an embodiment, the bank BNK may surround the first to third emission areas EA1, EA2, EA3 in a plan view. The bank BNK may include first and second banks BNK1 and BNK2.

The first bank BNK1 may be disposed on the etch control layer EST, and the second bank BNK2 may be disposed on the first bank BNK1. Side surfaces of the first bank BNK1 may be recessed inward from side surfaces of the second bank BNK2. In an embodiment, the side surfaces of the second bank BNK2 protrude from the side surfaces of the first bank BNK1 toward the first emission area EA1, and the second bank BNK2 may include protruding tips. Accordingly, an undercut structure may be formed under each tip of the second bank BNK2. A thickness of the first bank BNK1 may be greater than a thickness of the second bank BNK2.

The first and second banks BNK1 and BNK2 may include a groove GRV recessed from the upper surface of the bank BNK. The groove GRV may penetrate from the second bank BNK2 to a portion of the first bank BNK1. In a plan view, the groove GRV may be spaced apart from the first to third emission areas EA1, EA2, EA3 with the second bank BNK2 therebetween. The groove GRV may accommodate first to third organic patterns ELP1, ELP2, ELP3, first to third electrode patterns CEP1, CEP2, CEP3, and first to third capping patterns CLP1, CLP2, CLP3. For example, a depth of the groove GRV may be greater than a sum of a thickness of the first organic pattern ELP1, a thickness of the first electrode pattern CEP1, and a thickness of the first capping pattern CLP1, but is not limited thereto.

The first to third common electrodes CE1, CE2, CE3 may be in contact with the side surfaces of the first bank BNK1, and the first to third common electrodes CE1, CE2, CE3 may be electrically connected to each other by the first bank BNK1. For example, the first common electrode CE1 may receive a common voltage, a cathode voltage, or a low potential voltage.

FIGS. 10 through 17 are cross-sectional views illustrating a process of manufacturing a display device according to an embodiment.

In FIG. 10, first to third pixel electrodes AE1, AE2, AE3 may be spaced apart from each other on a thin-film transistor layer TFTL. The first to third pixel electrodes AE1, AE2, AE3 may include at least one of silver (Ag), copper (Cu), aluminum (Al), nickel (Ni), and lanthanum (La). For another example, the first to third pixel electrodes AE1, AE2, AE3 may include a material such as indium tin oxide (ITO), indium zinc oxide (IZO), or indium tin zinc oxide (ITZO). As another example, the first to third pixel electrodes AE1, AE2, AE3 may have a stacked structure of ITO/Ag/ITO, ITO/Ag/IZO, or ITO/Ag/ITZO/IZO.

A sacrificial layer SFL may be disposed on the first to third pixel electrodes AE1, AE2, AE3. The sacrificial layer SFL may be disposed between upper surfaces of the first to third pixel electrodes AE1, AE2, AE3 and a first insulating layer IL1. In an embodiment, the sacrificial layer SFL may include an oxide semiconductor. For example, the sacrificial layer SFL may include at least one of indium gallium zinc oxide (IGZO), zinc tin oxide (ZTO), and indium zinc oxide (IZO).

The first insulating layer IL1 may be disposed on the thin-film transistor layer TFTL and the sacrificial layer SFL. The first insulating layer IL1 may include an inorganic insulating material. The first insulating layer IL1 may include, but is not limited to, at least one of a silicon nitride layer, a silicon oxynitride layer, a silicon oxide layer, a titanium oxide layer, an aluminum oxide layer, and an amorphous silicon layer.

The etch control layer EST may be disposed on the first insulating layer IL1. The etch control layer EST may function as an etching stopper. Optionally, the etch control layer EST may be omitted.

A conductive layer MTL may be disposed on the etch control layer EST. In an embodiment, the conductive layer MTL may include a metal material with high electrical conductivity. For example, the conductive layer MTL may include, but is not limited to, aluminum (Al).

A first bank BNK1 may be disposed on the conductive layer MTL, and a second bank BNK2 may be disposed on the first bank BNK1. A thickness of the first bank BNK1 may be greater than a thickness of the second bank BNK2. In an embodiment, the first bank BNK1 may include a metal material having high electrical conductivity, and the second bank BNK2 may include a material having low reflectivity. For example, the first bank BNK1 may include aluminum (Al), and the second bank BNK2 may include titanium (Ti). However, the present disclosure is not limited thereto.

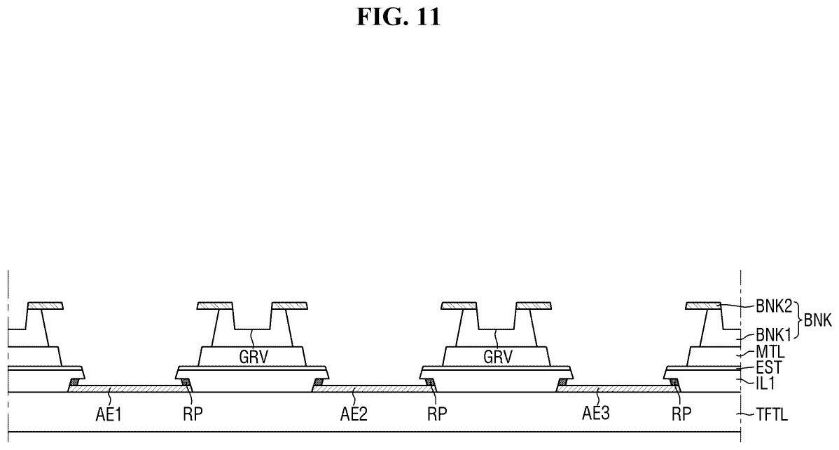

In FIG. 11, the second bank BNK2, the first bank BNK1, and the conductive layer MTL may be sequentially etched to form a plurality of holes. The holes may overlap first to third emission areas EA1, EA2, EA3. The conductive layer MTL and the first and second banks BNK1 and BNK2 may be etched by performing at least one of a dry etching process and a wet etching process. The etch control layer EST may protect the first to third pixel electrodes AE1, AE2, AE3 in the process of etching the bank BNK and the conductive layer MTL. The first and second banks BNK1 and BNK2 may include different metal materials, and etching rates of the first and second banks BNK1 and BNK2 may be different from each other. The etching rate of the first bank BNK1 may be higher than that of the second bank BNK2, and the first bank BNK1 may be etched more than the second bank BNK2. Therefore, a side shape of the first and second banks BNK1 and BNK2 may be determined by a difference in etching rate between the first and second banks BNK1 and BNK2. The second bank BNK2 may include tips protruding from the first bank BNK1 toward the holes. Side surfaces of the first bank BNK1 may be recessed inward from side surfaces of the second bank BNK2. An undercut structure may be formed under each tip of the second bank BNK2. A thickness of the first bank BNK1 may be greater than a thickness of the second bank BNK2.

For example, the groove GRV may be formed by being recessed from the upper surface of the bank BNK. The groove GRV may penetrate from the second bank BNK2 to a portion of the first bank BNK1. In a plan view, the groove GRV may be spaced apart from the first to third emission areas EA1, EA2, EA3 with the second bank BNK2 therebetween.

As another example, the groove GRV may penetrate from the upper surface of the second bank BNK2 to the lower surface of the first bank BNK1 to expose the upper surface of the conductive layer MTL.

The etch control layer EST, the first insulating layer IL1, and the sacrificial layer SFL may be etched by performing at least one of a dry etching process and a wet etching process. As the etch control layer EST, the first insulating layer IL1 and the sacrificial layer SFL are etched, and at least a portion of an upper surface of each of the first to third pixel electrodes AE1, AE2, AE3 may be exposed. The sacrificial layer SFL may be etched more than the first insulating layer IL1 in a plan view. When the sacrificial layer SFL is etched, residual patterns RP may remain between the first insulating layer IL1 and the first pixel electrode AE1. Accordingly, side surfaces of the residual patterns RP may be recessed inward from side surfaces of the first insulating layer IL1.

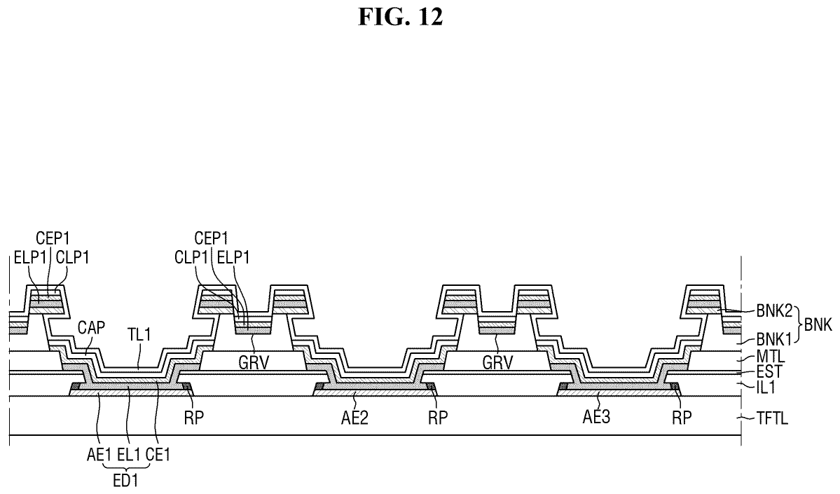

In FIG. 12, a first light emitting layer EL1 may be directly disposed on the first pixel electrode AE1 in the first emission area EA1. A portion of the first light emitting layer EL1 may fill a space surrounded by the first pixel electrode AE1, the residual patterns RP and the first insulating layer IL1, and another portion of the first light emitting layer EL1 may cover the side surfaces of the etch control layer EST and the upper surfaces of edges of the etch control layer EST and the side surfaces of the first insulating layer IL1.

In an embodiment, an organic material for forming the first light emitting layer EL1 and a first organic pattern ELP1 may be deposited on an entire surface of the display device 10. In an embodiment, the first light emitting layer EL1 and the first organic pattern ELP1 may be deposited in a same process and may be cut and separated by the tips of the second bank BNK2. A portion of the first organic pattern ELP1 may be disposed on the second bank BNK2 adjacent to the first emission area EA1, and another portion of the first organic pattern ELP1 may be accommodated in the groove GRV. The first organic pattern ELP1 may be directly disposed on the second pixel electrode AE2 in the second emission area EA2 and may be directly disposed on the third pixel electrode AE3 in the third emission area EA3.

A first common electrode CE1 may be directly disposed on the first light emitting layer EL1 in the first emission area EA1. The first common electrode CE1 may contact side surfaces of the conductive layer MTL and upper surfaces of edges of the conductive layer MTL. The first common electrode CE1 may include a transparent conductive material and transmit light generated from the first light emitting layer EL1. Therefore, a first light emitting element ED1 may be disposed in a hole formed by the bank BNK and may emit light through the first emission area EA1.

In an embodiment, a metal material for forming the first common electrode CE1 and a first electrode pattern CEP1 may be deposited on an entire surface of the display device 10. A portion of the first electrode pattern CEP1 may be disposed on the first organic pattern ELP1 on the second bank BNK2 and another portion of the first electrode pattern CEP1 may be disposed on the first organic pattern ELP1 in the groove GRV. In an embodiment, the first common electrode CE1 and the first electrode pattern CEP1 may be deposited in a same process and may be cut and separated by the tips of the second bank BNK2. The first electrode pattern CEP1 may be directly disposed on the first organic pattern ELP1 in each of the second and third emission areas EA2 and EA3. Therefore, the first electrode pattern CEP1 may be disposed on the first organic pattern ELP1 in areas other than the first emission area EA1.

A capping layer CAP may be disposed on the first common electrode CE1 in the first emission area EA1. The capping layer CAP may include an inorganic insulating material and may cover the first light emitting element ED1. The capping layer CAP may prevent or substantially prevent the first light emitting element ED1 from being damaged by external air. For example, the capping layer CAP may include, but is not limited to, at least one of a silicon nitride layer, a silicon oxynitride layer, a silicon oxide layer, a titanium oxide layer, an aluminum oxide layer, and an amorphous silicon layer.

In an embodiment, an inorganic material for forming the capping layer CAP and a first capping pattern CLP1 may be deposited on an entire surface of the display device 10. A portion of the first capping pattern CLP1 may be disposed on the first electrode pattern CEP1 on the second bank BNK2, and another portion of the first capping pattern CLP1 may be disposed on first electrode pattern CEP1 in the groove GRV. In an embodiment, the capping layer CAP and the first capping pattern CLP1 may be deposited in a same process and may be cut and separated by the tips of the second bank BNK2. The first capping pattern CLP1 may be disposed on the first electrode pattern CEP1 in each of the second and third emission areas EA2 and EA3. Therefore, the first capping pattern CLP1 may be disposed on the first electrode pattern CEP1 in areas other than the first emission area EA1.

In an embodiment, an inorganic material for forming a first inorganic layer TL1 may be deposited on an entire surface of the display device 10. The first inorganic layer TL1 may cover an upper surface of the capping layer CAP in the first emission area EA1 and may cover an upper surface of the first capping pattern CLP1 in the second and third emission areas EA2 and EA3. The first inorganic layer TL1 may cover the side surfaces of the first bank BNK1, lower and side surfaces of the tips of the second bank BNK2, side surfaces of the first organic pattern ELP1, side surfaces of the first electrode pattern CEP1, and upper and side surfaces of the first capping pattern CLP1 disposed on the second bank BNK2. The first inorganic layer TL1 may cover the upper surface of the first capping pattern CLP1 in the groove GRV. The first inorganic layer TL1 may include an inorganic material to prevent or substantially prevent oxygen or moisture from penetrating into the first light emitting element ED1. The first inorganic layer TL1 may be an inorganic encapsulation layer. For example, the first inorganic layer TL1 may include, but is not limited to, at least one of a silicon nitride layer, a silicon oxynitride layer, a silicon oxide layer, a titanium oxide layer, an aluminum oxide layer, and an amorphous silicon layer.

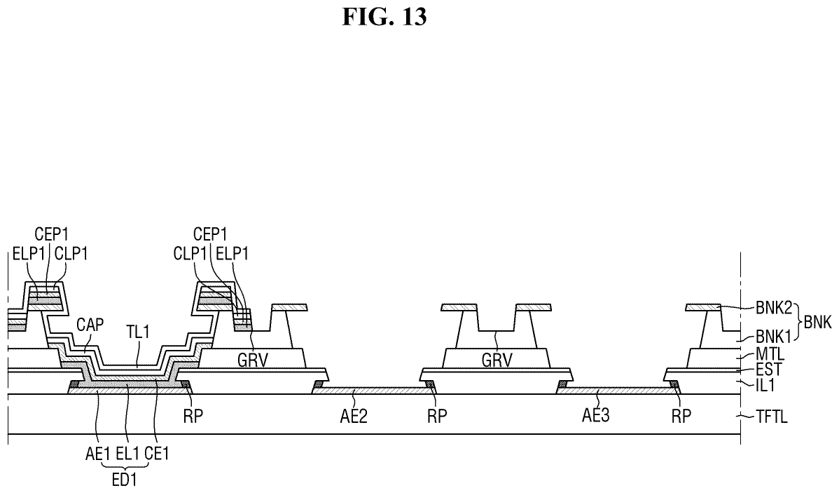

In FIG. 13, the first inorganic layer TL1, the first capping pattern CLP1, the first electrode pattern CEP1, and the first organic pattern ELP1 not disposed in the first emission area EA1 and an area adjacent to the first emission area EA1 may be etched through an etching process. For example, the first inorganic layer TL1, the first capping pattern CLP1, the first electrode pattern CEP1, and the first organic pattern ELP1 may be etched by performing at least one of a dry etching process and a wet etching process. Accordingly, the second pixel electrode AE2 may be exposed in the second emission area EA2, and the third pixel electrode AE3 may be exposed in the third emission area EA3.

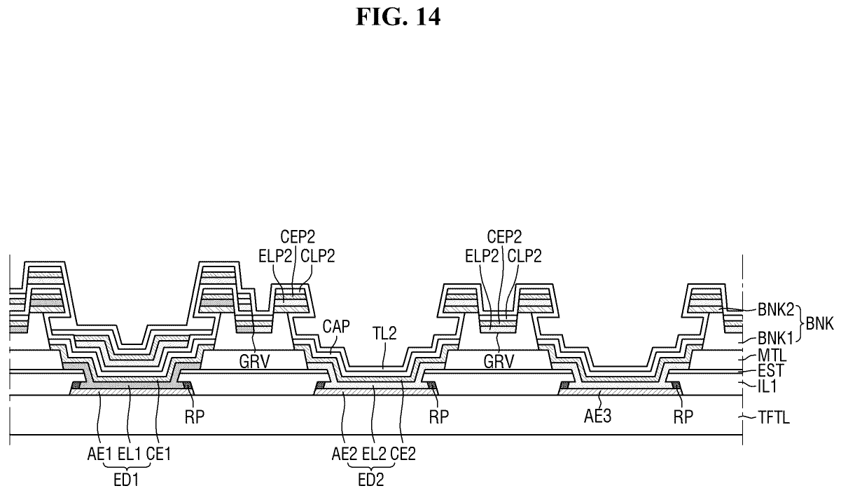

In FIG. 14, a second light emitting layer EL2 may be directly disposed on the second pixel electrode AE2 in the second emission area EA2. A portion of the second light emitting layer EL2 may fill a space surrounded by the second pixel electrode AE2, the residual patterns RP and the first insulating layer IL1, and another portion of the second light emitting layer EL2 may cover the side surfaces of the etch control layer EST and the upper surfaces of the edges of the etch control layer EST and the side surfaces of the first insulating layer IL1.

In an embodiment, an organic material for forming the second light emitting layer EL2 and a second organic pattern ELP2 may be deposited on an entire surface of the display device 10. In an embodiment, the second light emitting layer EL2 and the second organic pattern ELP2 may be deposited in a same process and may be cut and separated by the tips of the second bank BNK2. A portion of the second organic pattern ELP2 may be disposed on the second bank BNK2 adjacent to the second emission area EA2, and another portion of the second organic pattern ELP2 may be accommodated in the groove GRV. The second organic pattern ELP2 may be directly disposed on the third pixel electrode AE3 in the third emission area EA3.

A second common electrode CE2 may be directly disposed on the second light emitting layer EL2 in the second emission area EA2. The second common electrode CE2 may contact the side surfaces of the conductive layer MTL and the upper surfaces of the edges of the conductive layer MTL. The second common electrode CE2 may include a transparent conductive material and transmit light generated from the second light emitting layer EL2. Therefore, a second light emitting element ED2 may be disposed in a hole formed by the bank BNK and may emit light through the second emission area EA2.

In an embodiment, a metal material for forming the second common electrode CE2 and a second electrode pattern CEP2 may be deposited on an entire surface of the display device 10. A portion of the second electrode pattern CEP2 may be disposed on the second organic pattern ELP2 on the second bank BNK2, and another portion of the second electrode pattern CEP2 may be disposed on the second organic pattern ELP2 in the groove GRV. In an embodiment, the second common electrode CE2 and the second electrode pattern CEP2 may be deposited in a same process and may be cut and separated by the tips of the second bank BNK2. The second electrode pattern CEP2 may be directly disposed on the second organic pattern ELP2 in each of the first and third emission areas EA1 and EA3. Therefore, the second electrode pattern CEP2 may be disposed on the second organic pattern ELP2 in areas other than the second emission area EA2.

A capping layer CAP may be disposed on the second common electrode CE2 in the second emission area EA2. The capping layer CAP may include an inorganic insulating material and may cover the second light emitting element ED2. The capping layer CAP may prevent or substantially prevent the second light emitting element ED2 from being damaged by external air.

In an embodiment, an inorganic material for forming the capping layer CAP and a second capping pattern CLP2 may be deposited on an entire surface of the display device 10. A portion of the second capping pattern CLP2 may be disposed on the second electrode pattern CEP2 on the second bank BNK2, and another portion of the second capping pattern CLP2 may be disposed on the second electrode pattern CEP2 in the groove GRV. In an embodiment, the capping layer CAP and the second capping pattern CLP2 may be deposited in a same process and may be cut and separated by the tips of the second bank BNK2. The second capping pattern CLP2 may be disposed on the second electrode pattern CEP2 in each of the first and third emission areas EA1 and EA3. Therefore, the second capping pattern CLP2 may be disposed on the second electrode pattern CEP2 in the areas other than the second emission area EA2.

In an embodiment, an inorganic material for forming a second inorganic layer TL2 may be deposited on an entire surface of the display device 10. The second inorganic layer TL2 may cover an upper surface of the capping layer CAP in the second emission area EA2 and may cover an upper surface of the second capping pattern CLP2 in the first and third emission areas EA1 and EA3. The second inorganic layer TL2 may cover the side surfaces of the first bank BNK1, the lower and side surfaces of the tips of the second bank BNK2, side surfaces of the second organic pattern ELP2, side surfaces of the second electrode pattern CEP2, and upper and side surfaces of the second capping pattern CLP2 disposed on the second bank BNK2. The second inorganic layer TL2 may cover the upper surface of the second capping pattern CLP2 in the groove GRV. The second inorganic layer TL2 may include an inorganic material to prevent or substantially prevent oxygen or moisture from penetrating into the second light emitting element ED2. The second inorganic layer TL2 may be an inorganic encapsulation layer. For example, the second inorganic layer TL2 may be made of at least one of the materials described as an example of the first inorganic layer TL1.

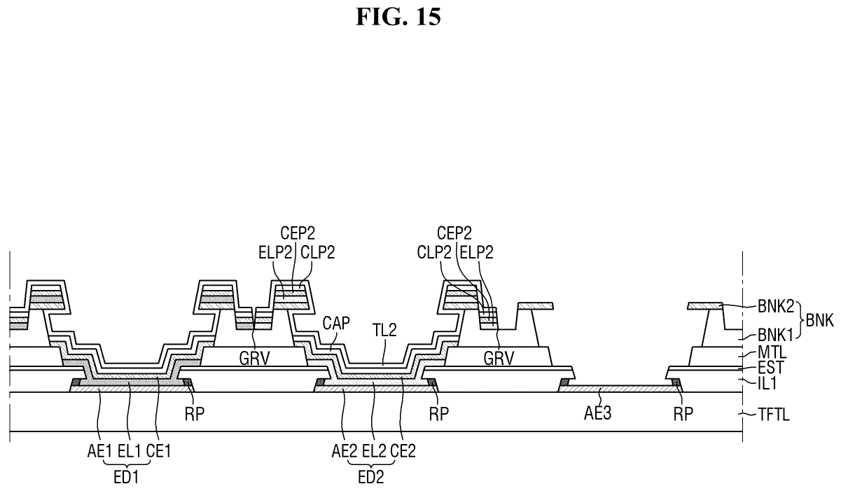

In FIG. 15, the second inorganic layer TL2, the second capping pattern CLP2, the second electrode pattern CEP2, and the second organic pattern ELP2 not disposed in the second emission area EA2 and an area adjacent to the second emission area EA2 may be etched through an etching process. For example, the second inorganic layer TL2, the second capping pattern CLP2, the second electrode pattern CEP2, and the second organic pattern ELP2 may be etched by performing at least one of a dry etching process and a wet etching process. Accordingly, the third pixel electrode AE3 may be exposed in the third emission area EA3.

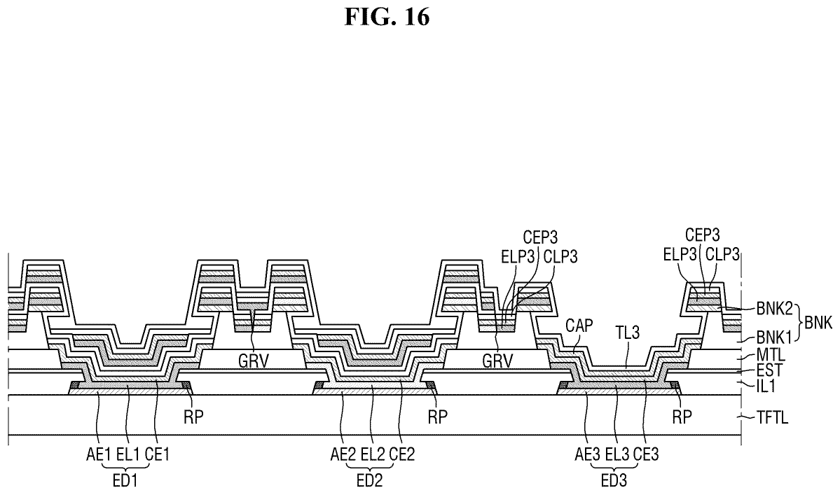

In FIG. 16, a third light emitting layer EL3 may be directly disposed on the third pixel electrode AE3 in the third emission area EA3. A portion of the third light emitting layer EL3 may fill a space surrounded by the third pixel electrode AE3, the residual patterns RP and the first insulating layer IL1, and another portion of the third light emitting layer EL3 may cover the side surfaces of the etch control layer EST and the upper surfaces of the edges of the etch control layer EST and the side surfaces of the first insulating layer IL1.

In an embodiment, an organic material for forming the third light emitting layer EL3 and a third organic pattern ELP3 may be deposited on an entire surface of the display device 10. In an embodiment, the third light emitting layer EL3 and the third organic pattern ELP3 may be deposited in a same process and may be cut and separated by the tips of the second bank BNK2. A portion of the third organic pattern ELP3 may be disposed on the second bank BNK2 adjacent to the third emission area EA3, and another portion of the third organic pattern ELP3 may be accommodated in the groove GRV.

A third common electrode CE3 may be directly disposed on the third light emitting layer EL3 in the third emission area EA3. The third common electrode CE3 may contact the side surfaces of the conductive layer MTL and the upper surfaces of the edges of the conductive layer MTL. The third common electrode CE3 may include a transparent conductive material and transmit light generated from the third light emitting layer EL3. Therefore, a third light emitting element ED3 may be disposed in a hole formed by the bank BNK and may emit light through the third emission area EA3.

In an embodiment, a metal material for forming the third common electrode CE3 and a third electrode pattern CEP3 may be deposited on an entire surface of the display device 10. A portion of the third electrode pattern CEP3 may be disposed on the third organic pattern ELP3 on the second bank BNK2, and another portion of the third electrode pattern CEP3 may be disposed on the third organic pattern ELP3 in the groove GRV. In an embodiment, the third common electrode CE3 and the third electrode pattern CEP3 may be deposited in a same process and may be cut and separated by the tips of the second bank BNK2. The third electrode pattern CEP3 may be directly disposed on the third organic pattern ELP3 in each of the first and second emission areas EA1 and EA2. Therefore, the third electrode pattern CEP3 may be disposed on the third organic pattern ELP3 in areas other than the third emission area EA3.

A capping layer CAP may be disposed on the third common electrode CE3 in the third emission area EA3. The capping layer CAP may include an inorganic insulating material and may cover the third light emitting element ED3. The capping layer CAP may prevent or substantially prevent the third light emitting element ED3 from being damaged by external air.

In an embodiment, an inorganic material for forming the capping layer CAP and a third capping pattern CLP3 may be deposited on an entire surface of the display device 10. A portion of the third capping pattern CLP3 may be disposed on the third electrode pattern CEP3 on the second bank BNK2, and another portion of the third capping pattern CLP3 may be disposed on the third electrode pattern CEP3 in the groove GRV. In an embodiment, the capping layer CAP and the third capping pattern CLP3 may be deposited in a same process and may be cut and separated by the tips of the second bank BNK2. The third capping pattern CLP3 may be disposed on the third electrode pattern CEP3 in each of the first and second emission areas EA1 and EA2. Therefore, the third capping pattern CLP3 may be disposed on the third electrode pattern CEP3 in the areas other than the third emission area EA3.

In an embodiment, an inorganic material for forming a third inorganic layer TL3 may be deposited on an entire surface of the display device 10. The third inorganic layer TL3 may cover an upper surface of the capping layer CAP in the third emission area EA3 and may cover the upper surface of the third capping pattern CLP3 in the first and second emission areas EA1 and EA2. The third inorganic layer TL3 may cover the side surfaces of the first bank BNK1, the lower and side surfaces of the tips of the second bank BNK2, side surfaces of the third organic pattern ELP3 disposed on the second bank BNK2, side surfaces of the third electrode pattern CEP3, and upper and side surfaces of the third capping pattern CLP3. The third inorganic layer TL3 may cover the upper surface of the third capping pattern CLP3 in the groove GRV. The third inorganic layer TL3 may include an inorganic material to prevent or substantially prevent oxygen or moisture from penetrating into the third light emitting element ED3. The third inorganic layer TL3 may be an inorganic encapsulation layer. For example, the third inorganic layer TL3 may be made of at least one of the materials described as examples of the first inorganic layer TL1.

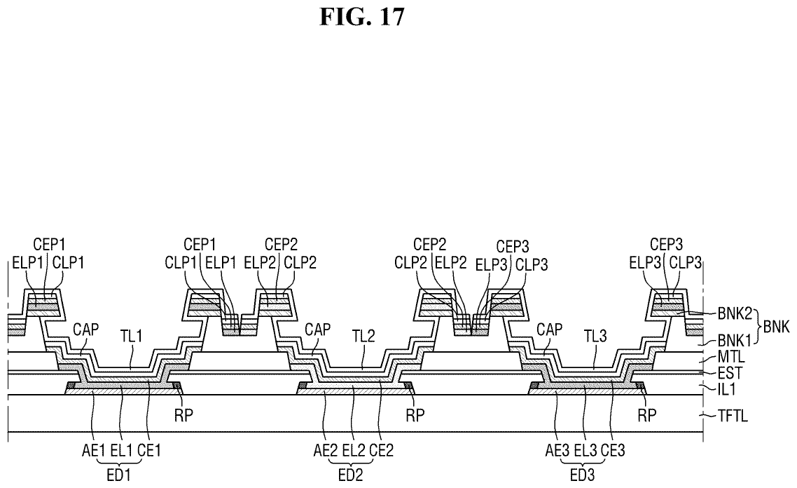

In FIG. 17, the third inorganic layer TL3, the third capping pattern CLP3, the third electrode pattern CEP3, and the third organic pattern ELP3 not disposed in the third emission area EA3 and an area adjacent to the third emission area EA3 may be etched through an etching process. For example, the third inorganic layer TL3, the third capping pattern CLP3, the third electrode pattern CEP3, and the third organic pattern ELP3 may be etched by performing at least one of a dry etching process and a wet etching process.

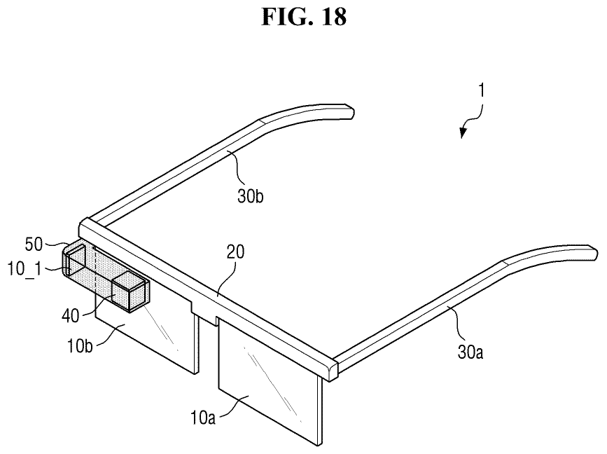

FIG. 18 illustrates a virtual reality device including a display device according to an embodiment. A display device 10_1 of FIG. 18 may include any of the display devices 10 according to the embodiments of FIGS. 1 through 9 described above.

Referring to FIG. 18, in an embodiment, a virtual reality device 1 may be a glasses-type display. The virtual reality device 1 may include the display device 10_1, a left lens 10a, a right lens 10b, a support frame 20, eyeglass frame legs 30a and 30b, a reflective member 40, and a display device housing 50.

In another embodiment, the virtual reality device 1 may be applied to a head mounted display including a head mounted band that can be worn on the head instead of the eyeglass frame legs 30a and 30b. Therefore, the virtual reality device 1 is not limited to that illustrated in FIG. 18 and can be applied in various forms to various other electronic devices.

The display device housing 50 may include the display device 10_1 and the reflective member 40. An image displayed on the display device 10_1 may be reflected by the reflective member 40 and provided to a user's right eye through the right lens 10b. Accordingly, the user can view a virtual reality image displayed on the display device 10_1 through the right eye.

The display device housing 50 may be disposed at a right end of the support frame 20. However, the position of the display device housing 50 is not limited thereto. For example, the display device housing 50 may be disposed at a left end of the support frame 20. In this case, an image displayed on the display device 10_1 may be reflected by the reflective member 40 and provided to a user's left eye through the left lens 10a. Therefore, the user can view a virtual reality image displayed on the display device 10_1 through the left eye.

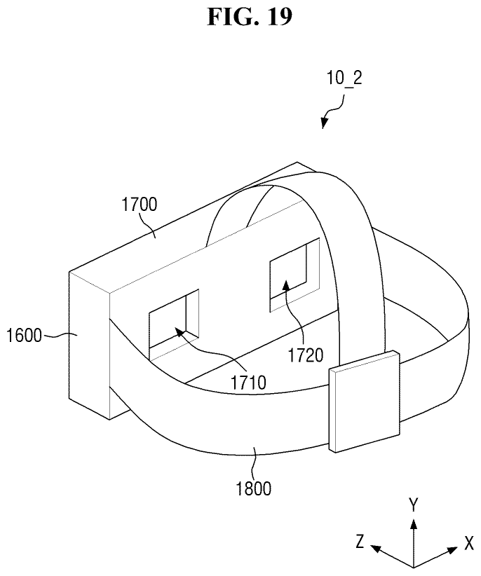

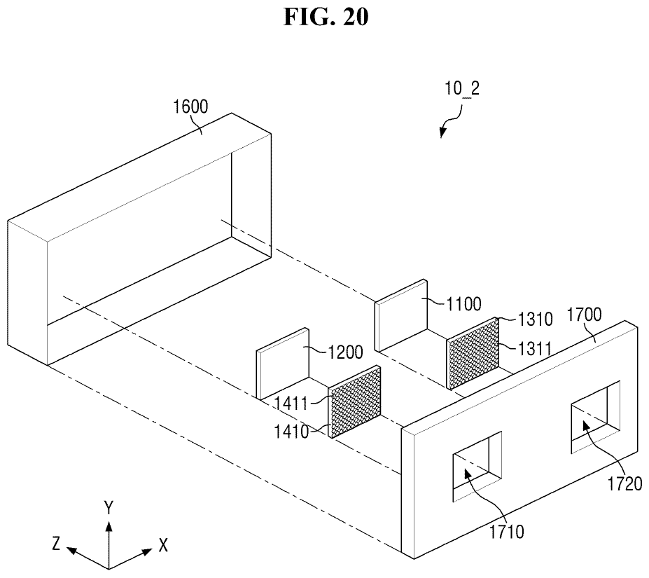

As another example, the display device housing 50 may be disposed at both the left and right ends of the support frame 20. In this case, a user can view a virtual reality image displayed on the display device 10_1 through both the left and right eyes. FIGS. 19 and 20 illustrate a head mounted display including a display device

according to an embodiment. A display device 10_2 of FIGS. 19 and 20 may include any of the display devices 10 according to the embodiments of FIGS. 1 through 9 described above.

Referring to FIGS. 19 and 20, the display device 10_2 may be applied to a head mounted display (HMD). A first display device 1100 may provide an image to a user's right eye, and a second display device 1200 may provide an image to the user's left eye.

A first lens array 1310 may be disposed between the first display device 1100 and a housing cover 1700. The first lens array 1310 may include a plurality of lenses 1311. The lenses 1311 may include convex lenses that are convex toward the housing cover 1700.

A second lens array 1410 may be disposed between the second display device 1200 and the housing cover 1700. The second lens array 1410 may include a plurality of lenses 1411. The lenses 1411 may include convex lenses that are convex toward the housing cover 1700.

A display panel housing 1600 may house the first display device 1100, the second display device 1200, the first lens array 1310, and the second lens array 1410. A surface of the display panel housing 1600 may be open to accommodate the first display device 1100, the second display device 1200, the first lens array 1310, and the second lens array 1410.

The housing cover 1700 may cover the open surface of the display panel housing 1600. The housing cover 1700 may include a first opening 1710 on which a user's left eye is placed and a second opening 1720 on which the user's right eye is placed. For example, the first opening 1710 and the second opening 1720 may be formed in a square shape, but the shapes of the first and second openings 1710 and 1720 are not limited thereto. As another example, the first and second openings 1710 and 1720 may be formed in a circular or oval shape. As another example, the first and second openings 1710 and 1720 may be integrated to form one opening.

The second opening 1720 may be aligned with the first display device 1100 and the first lens array 1310, and the first opening 1710 may be aligned with the second display device 1200 and the second lens array 1410. Therefore, a user can view an image of the first display device 1100, which is enlarged as a virtual image by the first lens array 1310, through the second opening 1720 and can view an image of the second display device 1200, which is enlarged as a virtual image by the second lens array 1410, through the first opening 1710.

In an embodiment, a head mounted band 1800 may fix the display panel housing 1600 to a user's head such that the first opening 1710 and the second opening 1720 of the housing cover 1700 are placed on the user's left and right eyes, respectively. The head mounted band 1800 may be connected to upper, left, and right surfaces of the display panel housing 1600.

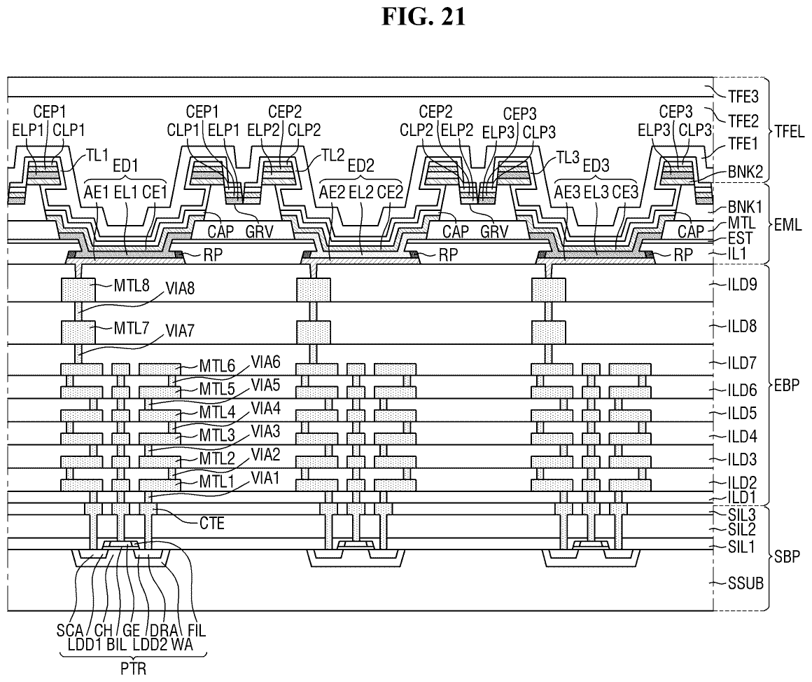

FIG. 21 is a cross-sectional view illustrating pixels according to an embodiment in the display devices of FIGS. 18 through 20. A display device of FIG. 21 may include the light emitting element layer EML and the encapsulation layer TFEL of FIG. 4. The same elements as those described above may be briefly described or may not be described.

Referring to FIG. 21, a display panel 100 may include a semiconductor backplane SBP, an emission backplane EBP, the light emitting element layer EML, and the encapsulation layer TFEL.

The semiconductor backplane SBP may include a semiconductor substrate SSUB, first to third semiconductor insulating layers SIL1 through SIL3, and contact terminals CTE.

In an embodiment, the semiconductor substrate SSUB may be a silicon substrate, a germanium substrate, or a silicon-germanium substrate. The semiconductor substrate SSUB may be a substrate doped with first-type impurities. A plurality of well areas WA may be disposed in an upper surface of the semiconductor substrate SSUB. The well areas WA may be areas doped with second-type impurities different from the first-type impurities. For example, the first-type impurities may be p-type impurities, and the second-type impurities may be n-type impurities. As another example, the first-type impurities may be n-type impurities, and the second-type impurities may be p-type impurities.

The semiconductor substrate SSUB may include a plurality of pixel transistors PTR. Each of the pixel transistors PTR may include a well area WA, a source area SCA, a drain area DRA, a channel area CH, a first lightly doped impurity area LDD1, a second lightly doped impurity area LDD2, a bottom insulating layer BIL, a gate electrode GE, and a side insulating layer FIL.

The well area WA may be disposed in an upper part of the semiconductor substrate SSUB. The well area WA may accommodate the source area SCA, the drain area DRA, the channel area CH, the first lightly doped impurity area LDD1, and the second lightly doped impurity area LDD2.

The source area SCA may correspond to a source electrode of a pixel transistor PTR, and the drain area DRA may correspond to a drain electrode of the pixel transistor PTR. Each of the source area SCA and the drain area DRA may be doped with the first-type impurities. The source area SCA may be disposed on a side of the gate electrode GE, and the drain area DRA may be disposed on another side of the gate electrode GE.

The channel area CH may be disposed between the source area SCA and the drain area DRA. The bottom insulating layer BIL may be disposed on the channel area CH to insulate the channel area CH from the gate electrode GE. The gate electrode GE may be disposed on the bottom insulating layer BIL. The gate electrode GE may overlap the channel area CH and the well area WA in the thickness direction. The side insulating layer FIL may be disposed on side surfaces of the gate electrode GE and an upper surface of the bottom insulating layer BIL.

The first lightly doped impurity area LDD1 may be disposed between the channel area CH and the source area SCA, and the second lightly doped impurity area LDD2 may be disposed between the channel area CH and the drain area DRA. The first lightly doped impurity area LDD1 may have a lower impurity concentration than the source area SCA due to the bottom insulating layer BIL. The second lightly doped impurity area LDD2 may have a lower impurity concentration than the drain area DRA due to the bottom insulating layer BIL. A distance between the source area SCA and the drain area DRA may be increased by the first lightly doped impurity area LDD1 and the second lightly doped impurity area LDD2. Accordingly, a length of the channel area CH of the pixel transistor PTR may increase, thereby preventing or substantially preventing punch-through and hot carrier phenomena caused by a short channel.

The first semiconductor insulating layer SIL1 may be disposed on the semiconductor substrate SSUB. The first semiconductor insulating layer SIL1 may include, but is not limited to, a silicon carbon nitride (SiCN) or silicon oxide (SiOx, 0<x≤2)-based inorganic material.

The second semiconductor insulating layer SIL2 may be disposed on the first semiconductor insulating layer SIL1. The second semiconductor insulating layer SIL2 may include, but is not limited to, a silicon oxide (SiOx)-based inorganic material.

The contact terminals CTE may be disposed on the second semiconductor insulating layer SIL2. Each of the contact terminals CTE may be connected to any of the gate electrode GE, the source area SCA, and the drain area DRA of a pixel transistor PTR through a hole penetrating the first semiconductor insulating layer SIL1 and the second semiconductor insulating layer SIL2. In an embodiment, the contact terminals CTE may include at least one of copper (Cu), aluminum (Al), tungsten (W), molybdenum (Mo), chromium (Cr), gold (Au), titanium (Ti), nickel (Ni), and neodymium (Nd).

The third semiconductor insulating layer SIL3 may be disposed on side surfaces of each of the contact terminals CTE. An upper surface of each of the contact terminals CTE may be exposed without being covered by the third semiconductor insulating layer SIL3. The third semiconductor insulating layer SIL3 may include, but is not limited to, a silicon oxide (SiOx)-based inorganic material.

In an embodiment, the emission backplane EBP may include first to eighth metal layers MTL1 to MTL8, first to eighth vias VIA1 to VIA8, and first to ninth interlayer insulating layers ILD1 to ILD9.

The first to eighth metal layers MTL1 to MTL8 may be electrically connected to the contact terminals CTE exposed in the semiconductor backplane SBP to form each pixel circuit. For example, the semiconductor backplane SBP may include a plurality of pixel transistors PTR, and the emission backplane EBP may include a connection electrode connecting the pixel transistors PTR and at least one capacitor connected to each of the pixel transistors PTR. The emission backplane EBP may electrically connect a pixel circuit to a first light emitting element ED1.

The first interlayer insulating layer ILD1 may be disposed on the semiconductor backplane SBP. The first vias VIA1 may penetrate the first interlayer insulating layer ILD1 and may be connected to the contact terminals CTE exposed in the semiconductor backplane SBP. The first metal layers MTL1 may be disposed on the first interlayer insulating layer ILD1 and connected to the first vias VIA1.

The second interlayer insulating layer ILD2 may be disposed on the first interlayer insulating layer ILD1 and the first metal layers MTL1. The second vias VIA2 may penetrate the second interlayer insulating layer ILD2 and may be connected to the first metal layers MTL1. The second metal layers MTL2 may be disposed on the second interlayer insulating layer ILD2 and connected to the second vias VIA2.

The third interlayer insulating layer ILD3 may be disposed on the second interlayer insulating layer ILD2 and the second metal layers MTL2. The third vias VIA3 may penetrate the third interlayer insulating layer ILD3 and may be connected to the second metal layers MTL2. The third metal layers MTL3 may be disposed on the third interlayer insulating layer ILD3 and connected to the third vias VIA3.

The fourth interlayer insulating layer ILD4 may be disposed on the third interlayer insulating layer ILD3 and the third metal layers MTL3. The fourth vias VIA4 may penetrate the fourth interlayer insulating layer ILD4 and may be connected to the third metal layers MTL3. The fourth metal layers MTL4 may be disposed on the fourth interlayer insulating layer ILD4 and connected to the fourth vias VIA4.

The fifth interlayer insulating layer ILD5 may be disposed on the fourth interlayer insulating layer ILD4 and the fourth metal layers MTL4. The fifth vias VIA5 may penetrate the fifth interlayer insulating layer ILD5 and may be connected to the fourth metal layers MTL4. The fifth metal layers MTL5 may be disposed on the fifth interlayer insulating layer ILD5 and connected to the fifth vias VIA5.

The sixth interlayer insulating layer ILD6 may be disposed on the fifth interlayer insulating layer ILD5 and the fifth metal layers MTL5. The sixth vias VIA6 may penetrate the sixth interlayer insulating layer ILD6 and may be connected to the fifth metal layers MTL5. The sixth metal layers MTL6 may be disposed on the sixth interlayer insulating layer ILD6 and connected to the sixth vias VIA6.

The seventh interlayer insulating layer ILD7 may be disposed on the sixth interlayer insulating layer ILD6 and the sixth metal layers MTL6. The seventh vias VIA7 may penetrate the seventh interlayer insulating layer ILD7 and may be connected to the sixth metal layers MTL6. The seventh metal layers MTL7 may be disposed on the seventh interlayer insulating layer ILD7 and connected to the seventh vias VIA7.

The eighth interlayer insulating layer ILD8 may be disposed on the seventh interlayer insulating layer ILD7 and the seventh metal layers MTL7. The eighth vias VIA8 may penetrate the eighth interlayer insulating layer ILD8 and may be connected to the seventh metal layers MTL7. The eighth metal layers MTL8 may be disposed on the eighth interlayer insulating layer ILD8 and connected to the eighth vias VIA8. The ninth interlayer insulating layer ILD9 may be disposed on the eighth interlayer insulating layer ILD8 and the eighth metal layers MTL8.

In an embodiment, the first to eighth metal layers MTL1 to MTL8 and the first to eighth vias VIA1 to VIA8 may include substantially a same material. In an embodiment, the first to eighth metal layers MTL1 to MTL8 and the first to eighth vias VIA1 to VIA8 may include at least one of copper (Cu), aluminum (Al), tungsten (W), molybdenum (Mo), chromium (Cr), gold (Au), titanium (Ti), nickel (Ni), and neodymium (Nd). Each of the first to ninth interlayer insulating layers ILD1 to ILD9 may include, but is not limited to, a silicon oxide (SiOx)-based inorganic material.

A thickness of the first metal layers MTL1, a thickness of the second metal layers MTL2, a thickness of the third metal layers MTL3, a thickness of the fourth metal layers MTL4, a thickness of the fifth metal layers MTL5, and a thickness of the sixth metal layers MTL6 may each be greater than each of a thickness of the first vias VIA1, a thickness of the second vias VIA2, a thickness of the third vias VIA3, a thickness of the fourth vias VIA4, a thickness of the fifth vias VIA5, and a thickness of the sixth vias VIA6. The thickness of the second metal layers MTL2, the thickness of the third metal layers MTL3, the thickness of the fourth metal layers MTL4, the thickness of the fifth metal layers MTL5, and the thickness of the sixth metal layers MTL6 may each be greater than the thickness of the first metal layers MTL1. The thickness of the second metal layers MTL2, the thickness of the third metal layers MTL3, the thickness of the fourth metal layers MTL4, the thickness of the fifth metal layers MTL5, and the thickness of the sixth metal layers MTL6 may be substantially the same. For example, the thickness of the first metal layers MTL1 may be about 1360 Å, the thickness of the second metal layers MTL2, the thickness of the third metal layers MTL3, the thickness of the fourth metal layers MTL4, the thickness of the fifth metal layers MTL5, and the thickness of the sixth metal layers MTL6 may each be about 1440 Å, and the thickness of the first vias VIA1, the thickness of the second vias VIA2, the thickness of the third vias VIA3, the thickness of the fourth vias VIA4, the thickness of the fifth vias VIA5 and the thickness of the sixth vias VIA6 may each be about 1150 Å.

A thickness of the seventh metal layers MTL7 and a thickness of the eighth metal layers MTL8 may each be greater than each of the thickness of the first metal layers MTL1, the thickness of the second metal layers MTL2, the thickness of the third metal layers MTL3, the thickness of the fourth metal layers MTL4, the thickness of the fifth metal layers MTL5, and the thickness of the sixth metal layers MTL6. The thickness of the seventh metal layers MTL7 and the thickness of the eighth metal layers MTL8 may each be greater than each of a thickness of the seventh vias VIA7 and a thickness of the eighth vias VIA8. The thickness of the seventh vias VIA7 and the thickness of the eighth vias VIA8 may each be greater than each of the thickness of the first vias VIA1, the thickness of the second vias VIA2, the thickness of the third vias VIA3, the thickness of the fourth vias VIA4, the thickness of the fifth vias VIA5, and the thickness of the sixth vias VIA6. The thickness of the seventh metal layers MTL7 and the thickness of the eighth metal layers MTL8 may be substantially the same. For example, the thickness of the seventh metal layers MTL7 and the thickness of the eighth metal layers MTL8 may each be about 9000 Å. For example, the thickness of the seventh vias VIA7 and the thickness of the eighth vias VIA8 may each be about 6000 Å.

The display device 10 may include a large number of pixels SP in a relatively small area as its resolution increases. The emission backplane EBP including the first to eighth metal layers MTL1 to MTL8 may implement a connection electrode connecting the pixel transistors PTR and at least one capacitor connected to each of the pixel transistors PTR, thereby implementing pixel circuits in a relatively small area. Therefore, the light emitting element layer EML can be formed on a silicon wafer (Si-wafer) including the semiconductor backplane SBP and the emission backplane EBP, and the display device 10 can realize ultra-high resolution image quality.

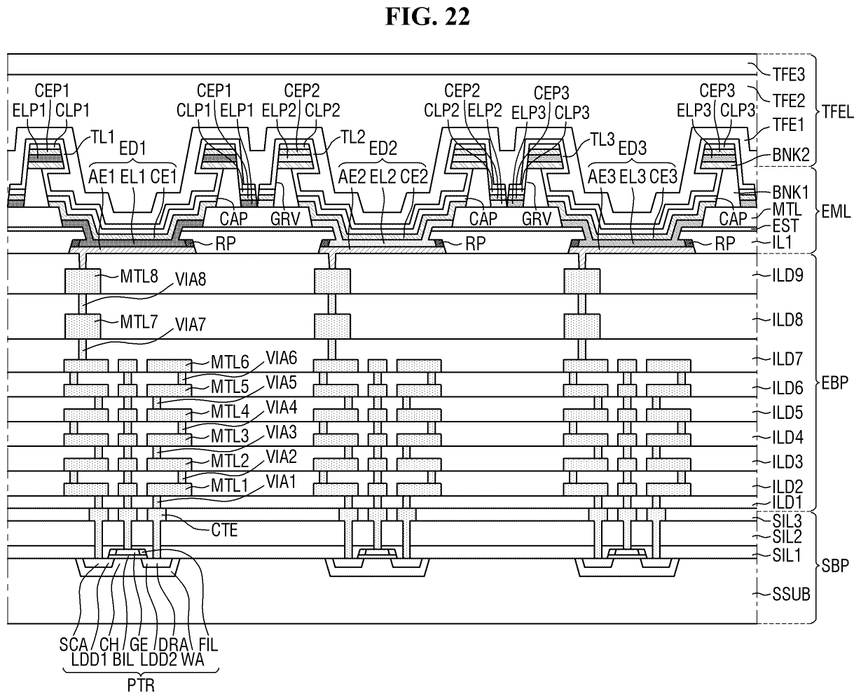

FIG. 22 is a cross-sectional view illustrating pixels according to an embodiment in the display devices of FIGS. 18 through 20. A display device of FIG. 22 may include the semiconductor backplane SBP and the emission backplane EBP of FIG. 21 and may include the light emitting element layer EML and the encapsulation layer TFEL of FIG. 6. Therefore, further description of the display device of FIG. 22 will be omitted.

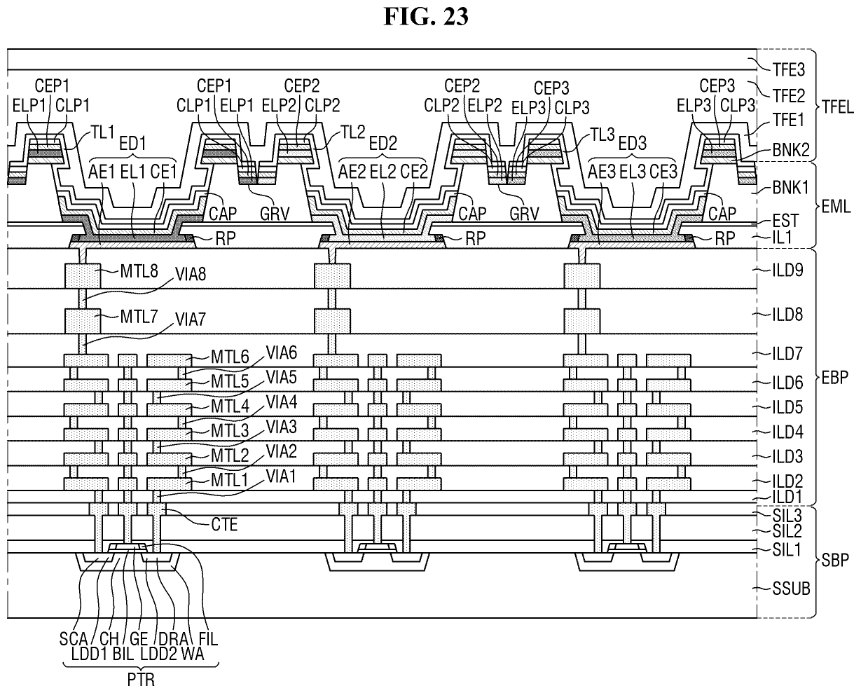

FIG. 23 is a cross-sectional view illustrating pixels according to an embodiment in the display devices of FIGS. 18 through 20. A display device of FIG. 23 may include the semiconductor backplane SBP and the emission backplane EBP of FIG. 21 and may include the light emitting element layer EML and the encapsulation layer TFEL of FIG. 8. Therefore, further description of the display device of FIG. 23 will be omitted.

What is claimed is:

1. A display device comprising:
a first pixel electrode located in a first emission area of a substrate;
an insulating layer covering an edge of the first pixel electrode;
a first light emitting layer on the first pixel electrode and the insulating layer;
a first common electrode on the first light emitting layer;
a conductive layer arranged on the insulating layer to surround the first emission area;
a first bank on the conductive layer;
a second bank adjacent to the first emission area on the first bank and comprising a tip protruding from sides of the first bank;
a groove recessed from an upper surface of the second bank to at least a portion of the first bank;
a first organic pattern comprising a same material as the first light emitting layer, wherein a portion of the first organic pattern is on the second bank, and another portion of the first organic pattern is accommodated in the groove; and
a first inorganic layer covering an upper surface of the first common electrode, and side surfaces of the first organic pattern arranged on the second bank and an upper surface of the first organic pattern accommodated in the groove.

2. The display device of claim 1, wherein the groove is spaced apart from the first emission area with the second bank located therebetween in a plan view.

3. The display device of claim 1, further comprising:
a first electrode pattern comprising a same material as the first common electrode,
wherein a portion of the first electrode pattern is on the first organic pattern on the second bank and another portion of the first electrode pattern is on the first organic pattern in the groove.

4. The display device of claim 3, further comprising:
a capping layer on the first common electrode; and
a first capping pattern comprising a same material as the capping layer,
wherein a portion of the first capping pattern is on the first electrode pattern on the second bank and another portion of the first capping pattern is on the first electrode pattern in the groove.

5. The display device of claim 4, wherein the first inorganic layer covers side surfaces of the first electrode pattern on the second bank, upper and side surfaces of the first capping pattern arranged on the second bank, and an upper surface of the first capping pattern in the groove.

6. The display device of claim 4, wherein a depth of the groove is greater than a sum of a thickness of the first organic pattern, a thickness of the first electrode pattern, and a thickness of the first capping pattern.

7. The display device of claim 1, further comprising:
a second pixel electrode located in a second emission area of the substrate;
a second light emitting layer on the second pixel electrode; and
a second common electrode on the second light emitting layer.

8. The display device of claim 7, wherein each of the first and second common electrodes is in contact with side surfaces of the conductive layer and upper surfaces of edges of the conductive layer.

9. The display device of claim 7, wherein the first and second common electrodes are electrically connected through the conductive layer.

10. The display device of claim 7, further comprising:
a second organic pattern comprising a same material as the second light emitting layer, wherein a portion of the second organic pattern is on the second bank and another portion of the second organic pattern is accommodated in the groove; and
a second electrode pattern comprising a same material as the second common electrode, wherein a portion of the second electrode pattern is on the second organic pattern on the second bank and another portion of the second electrode pattern is on the second organic pattern in the groove.

11. The display device of claim 10, further comprising a second inorganic layer covering an upper surface of the second common electrode, side surfaces of the second organic pattern arranged on the second bank, side surfaces of the second electrode pattern arranged on the second bank, and an upper surface of the second electrode pattern accommodated in the groove.

12. The display device of claim 1, wherein the groove penetrates from the upper surface of the second bank to a lower surface of the first bank to expose an upper surface of the conductive layer.

13. The display device of claim 12, wherein the another portion of the first organic pattern is accommodated in the groove to be directly disposed on the conductive layer.

14. A display device comprising:
a first pixel electrode located in a first emission area of a substrate;
an insulating layer covering an edge of the first pixel electrode;
a first light emitting layer on the first pixel electrode and the insulating layer;
a first common electrode on the first light emitting layer;
a first bank arranged on the insulating layer to surround the first emission area;
a second bank arranged adjacent to the first emission area on the first bank and comprising a tip protruding from sides of the first bank;
a groove recessed from an upper surface of the second bank to at least a portion of the first bank; and
a first organic pattern comprising a same material as the first light emitting layer, wherein a portion of the first organic pattern is on the second bank, and another portion of the first organic pattern is accommodated in the groove.

15. The display device of claim 14, further comprising:
a first electrode pattern comprising a same material as the first common electrode, wherein a portion of the first electrode pattern is arranged on the first organic pattern on the second bank, and another portion of the first electrode pattern is arranged on the first electrode pattern accommodated in the groove; and
a first inorganic layer covering an upper surface of the first common electrode, side surfaces of the first organic pattern arranged on the second bank, side surfaces of the first electrode pattern arranged on the second bank, and an upper surface of the first electrode pattern accommodated in the groove.

16. A method of manufacturing a display device, the method comprising:
forming first and second pixel electrodes on a substrate;
sequentially stacking a sacrificial layer, an insulating layer, a conductive layer, a first bank, and a second bank on the first and second pixel electrodes;
forming tips of the second bank which protrude from sides of the first bank by etching the second bank, the first bank, and the conductive layer, and forming a groove recessed from an upper surface of the second bank to at least a portion of the first bank;
exposing the first and second pixel electrodes by etching the insulating layer and the sacrificial layer; and
forming a first light emitting layer on the first pixel electrode, forming a portion of a first organic pattern on the second bank, and forming another portion of the first organic pattern in the groove.

17. The method of claim 16, further comprising:
forming a first common electrode on the first light emitting layer, forming a portion of a first electrode pattern on the first organic pattern on the second bank, and forming another portion of the first electrode pattern on the first organic pattern on the groove; and
forming a capping layer on the first common electrode, forming a portion of a first capping pattern on the first electrode pattern on the second bank, and forming another portion of the first capping pattern on the first electrode pattern in the groove.

18. The method of claim 17, further comprising forming a first inorganic layer covering an upper surface of the capping layer, side surfaces of the first organic pattern on the second bank, side surfaces of the first electrode pattern on the second bank, upper and side surfaces of the first capping pattern on the second bank, and an upper surface of the first capping pattern in the groove.

19. The method of claim 18, further comprising etching the first inorganic layer, the capping layer, the first capping pattern, the first electrode pattern, and the first organic pattern overlapping the second pixel electrode.

20. The method of claim 19, further comprising forming a second light emitting layer on the second pixel electrode, forming a portion of a second organic pattern on the second bank, and forming another portion of the second organic pattern in the groove.
